(19) United States
(12) Patent Application Publication
(10) Pub. No.: US 2025/0085310 A1
(43) Pub. Date: Mar. 13, 2025

(54) RESISTANCE MEASUREMENTS IN ELECTRICAL CHARACTERIZATION SYSTEM

(71) Applicant: International Business Machines Corporation, Armonk, NY (US)

(72) Inventors: Eric Zhang, Sleepy Hollow, NY (US); Jason S. Orcutt, Katonah, NY (US); Yves Martin, Yorktown Heights, NY (US)

(21) Appl. No.: 18/244,566

(22) Filed: Sep. 11, 2023

(51) Int. Cl. G01R 1/067; G01R 27/20

(52) U.S. Cl. CPC G01R 1/06794; G01R 27/205

(57) ABSTRACT

A system comprises a prober unit, and a control unit. The prober unit comprises electrical probes. The control unit configured to: cause the prober unit to make contact between the electrical probes and contact pads of a target device; cause the prober unit to increment a contact overdrive by a specified amount to increase a contact pressure between the electrical probes and the contact pads of the target device; measure a contact resistance between the electrical probes and the contact pads of the target device, subsequent to incrementing the contact overdrive; compare the measured contact resistance with a contact resistance threshold; and determine whether to perform an electrical characterization measurement of the target device, based on a result of comparing the measured contact resistance with the contact resistance threshold.

### BACKGROUND

This disclosure relates generally to techniques for performing resistance measurements using an electrical characterization system (e.g., a prober system) and, in particular, techniques for measuring junction resistances of superconducting tunnel junction devices (e.g., Josephson junctions) in conjunction with laser tuning superconducting tunnel junction devices. A quantum computing system can be implemented using superconducting circuit quantum electrodynamics (cQED) architectures that are constructed using quantum circuit components such as, e.g., superconducting quantum bits (e.g., fixed-frequency transmon quantum bits), superconducting quantum interference devices (SQUIDs), and other types of superconducting devices which comprise Josephson junction devices. In particular, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures. A fixed-frequency qubit, such as a transmon qubit, has a transition frequency (denoted f₀₁) which corresponds to an energy difference between a ground state |0> and a first excited state |1> of the qubit. It is known that the transition frequency f₀₁ of a qubit can be estimated from the tunnel junction resistance (denoted R_{J}) of the Josephson junction of the qubit.

A solid-state quantum processor can include multiple superconducting qubits that are arranged in a given lattice structure (e.g., square lattice, heavy hexagonal lattice) to enable quantum information processing through quantum gate operations (e.g., single-qubit gate operations and multi-qubit gate operations) in which quantum information is generated and encoded in computational basis states (e.g., |0> and |1>) of single qubits, superpositions of the computational basis states of single qubits, and/or entangled states of multiple qubits. Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more.

Scaling the number of qubits (e.g., fixed frequency transmon qubits) in a qubit lattice, while maintaining high-fidelity quantum gate operations, remains a key challenge for quantum computing. For example, as superconducting quantum processors scale to larger numbers of qubits, frequency crowding within a qubit lattice becomes increasingly problematic since the transition frequencies of the qubits need to be precisely controlled to minimize gate errors that can arise from lattice frequency collisions (e.g., improper detuning between superconducting qubits can reduce the fidelity of multi-qubit gate entanglement operations). Due to semiconductor processing variabilities, however, the transition frequencies of superconducting qubits as fabricated can deviate from design targets.

In this regard, laser annealing techniques can be used to adjust qubit frequencies post-fabrication and thereby selectively tune fixed-frequency qubits of a given qubit lattice into desired frequency patterns. In particular, laser annealing techniques can be utilized to increase collision-free yield of fixed-frequency qubit lattices by selectively trimming (i.e., tuning) individual qubit frequencies, post-fabrication, by enabling localized thermal annealing the Josephson junctions of the qubits to thereby adjust and stabilize the tunnel junction resistance R_{J} of the respective Josephson junctions (and correspondingly, the respective qubit transition frequencies f₀₁) with high precision. The tuning of qubit transition frequencies through laser thermal annealing, however, is non-trivial due to, e.g., inherent variabilities of the laser thermal anneal process itself and/or the equipment that is utilized to perform such laser thermal annealing, post fabrication, to tune the qubit transition frequencies in a given qubit lattice. Furthermore, during a process of laser tuning Josephson junctions, junction resistance measurements must be performed to determine if qubit frequency targets have been met. In this regard, non-destructive, reliable and accurate junction resistance measurements are critical when laser tuning Josephson junctions.

### SUMMARY

Exemplary embodiments of the disclosure include techniques for performing electrical characterization measurements of devices using an electrical characterization system (e.g., a prober unit) that is configured to perform contact quality check operations to enable non-destructive electrical probing with low contact resistance and stable contacts between electrical probes and test pads of the devices to be characterized.

For example, an exemplary embodiment includes a system which comprises a prober unit, and a control unit. The prober unit comprises electrical probes. The control unit is configured to: cause the prober unit to make contact between the electrical probes and contact pads of a target device; cause the prober unit to increment a contact overdrive by a specified amount to increase a contact pressure between the electrical probes and the contact pads of the target device; measure a contact resistance between the electrical probes and the contact pads of the target device, subsequent to incrementing the contact overdrive; compare the measured contact resistance with a contact resistance threshold; and determine whether to perform an electrical characterization measurement of the target device, based on a result of comparing the measured contact resistance with the contact resistance threshold.

Advantageously, in an electrical characterization system, the control unit performs a contact overdrive operation to achieve a quality electrical contact (e.g., low contact resistance) between the electrical probes and the contact pads of the target device, before performing the electrical characterization measurement of the target device.

In another exemplary embodiment, as may be combined with the preceding paragraphs, the control unit is configured to perform the electrical characterization measurement of the target device, in response to determining that the measured contact resistance is less than the contact resistance threshold. In response to determining that the measured contact resistance is not less than the contact resistance threshold, the control unit is configured to: cause the prober unit to incrementally increase the amount of contact overdrive by one or more contact overdrive increments of a specified fixed amount; remeasure the contact resistance between the electrical probes and the contact pads of the target device, subsequent to each contact overdrive increment of the specified fixed amount; and perform the electrical characterization measurement when the remeasured contact resistance between the electrical probes and the contact pads of the target device is determined to be less than the contact resistance threshold.

Advantageously, in the electrical characterization system, the control unit performs a contact overdrive operation in an incremental manner to apply a minimal amount of contact overdrive to achieve a quality electrical contact (e.g., low contact resistance), before performing the electrical characterization measurement of the target device (e.g., measurement of a junction resistance of a Josephson junction). The minimal contact overdrive serves to apply a minimum possible contact force on the electrical probes to enable non-destructive and accurate electrical characterization measurements.

In another exemplary embodiment, as may be combined with the preceding paragraphs, the control unit is configured to: cause the prober unit to incrementally increase the amount of contact overdrive to no more than a specified maximum amount of contact overdrive; and skip the electrical characterization measurement of the target device, in response to determining that the contact resistance between the electrical probes and the contact pads of the target device is still not less than the contact resistance threshold after a total amount of contact overdrive has reached the specified maximum amount of contact overdrive.

In another exemplary embodiment, as may be combined with the preceding paragraphs, in determining whether to perform the electrical characterization measurement of the target device, based on the result of comparing the measured contact resistance with the contact resistance threshold, the control unit is configured to: perform a contact stability check process to determine whether the contact between the electrical probes and contact pads of the target device is stable, in response to determining that the measured contact resistance is less than the contact resistance threshold; and perform the electrical characterization measurement, in response to determining that the contact between the electrical probes and contact pads of the target device is stable.

Advantageously, in addition to achieving, e.g., low contact resistance, the control unit performs a contact stability check to ensure that the electrical contact between the electrical probes and the contact pads of the target device are stable (e.g., not intermittent contact) before performing the electrical characterization measurement. The contact stability check serves to protect against performing the electrical characterization measurement with unstable electrical contacts between the electrical probes and the contact pads of the target device, which can cause, e.g., voltage spikes during the electrical characterization measurement and potentially damage the target device being measured.

In another exemplary embodiment, as may be combined with the preceding paragraphs, in performing the contact stability check process, the control unit is configured to: repeat a contact resistance measurement operation for a specified number of times, to obtain a plurality of contact resistance measurements; determine an amount of variation of the plurality of contact resistance measurements; and determine whether the contact between the electrical probes and the contact pads of the target device is stable, based on the determined amount of variation.

In another exemplary embodiment, as may be combined with the preceding paragraphs, the control unit is configured to: cause the prober unit to increase the amount of contact overdrive by a specified fixed amount, in response to determining that the contact between the electrical probes and contact pads of the target device is not stable; and repeat the contact stability check process with the contact between the electrical probes and contact pads of the target device at the increased amount of contact overdrive.

In another exemplary embodiment, as may be combined with the preceding paragraphs, the control unit is configured to skip the electrical characterization measurement of the target device, in response to the control unit determining that the contact between the electrical probes and the contact pads of the target device is still not stable after a total amount of contact overdrive has reached a specified maximum amount of contact overdrive.

In another exemplary embodiment, as may be combined with the preceding paragraphs, the electrical probes comprise a 4-wire probe, and the electrical characterization measurement comprises a 4-wire resistance measurement operation to measure a resistance of the target device.

Another exemplary embodiment includes a system which comprises an optical unit, a prober unit, and a control unit configured to control the prober unit and the optical unit. The optical unit and the prober unit comprise an integrated configuration to perform laser annealing operations for tuning junction resistances of superconducting tunnel junction devices on a quantum chip, and to perform in situ resistance measurements to measure the junction resistances of the superconducting tunnel junction devices on the quantum chip. In performing an in situ resistance measurement to measure a junction resistance of a target superconducting tunnel junction device, the control unit is configured to: cause the prober unit to make contact between the electrical probes and contact pads of the target superconducting tunnel junction device; cause the prober unit to increment a contact overdrive by a specified amount to increase a contact pressure between the electrical probes and the contact pads of the target superconducting tunnel junction device; measure a contact resistance between the electrical probes and the contact pads of the target superconducting tunnel junction device, subsequent to incrementing the contact overdrive; compare the measured contact resistance with a contact resistance threshold; and determine whether to perform the in situ resistance measurement to measure the junction resistance of the target superconducting tunnel junction device, based on a result of comparing the measured contact resistance with the contact resistance threshold.

In another exemplary embodiment, as may be combined with the preceding paragraphs, in determining whether to perform the in situ resistance measurement to measure the junction resistance of the target superconducting tunnel junction device, based on the result of comparing the measured contact resistance with the contact resistance threshold, the control unit is configured to: perform a contact stability check process to determine whether the contact between the electrical probes and contact pads of the target superconducting tunnel junction device is stable, in response to determining that the measured contact resistance is less than the contact resistance threshold; and perform the in situ resistance measurement, in response to determining that the contact between the electrical probes and contact pads of the target superconducting tunnel junction device is stable.

In another exemplary embodiment, as may be combined with the preceding paragraphs, in performing the contact stability check process, the control unit is configured to: repeat a contact resistance measurement operation for a specified number of times, to obtain a plurality of contact resistance measurements; determine an amount of variation of the plurality of contact resistance measurements; and determine whether the contact between the electrical probes and the contact pads of the target superconducting tunnel junction device is stable, based on the determined amount of variation.

In another exemplary embodiment, as may be combined with the preceding paragraphs, the control unit is configured to: cause the prober unit to increase the amount of contact overdrive by a specified fixed amount, in response to determining that the contact between the electrical probes and the contact pads of the target superconducting tunnel junction device is not stable; repeat the contact stability check process with the contact between the electrical probes and contact pads of the target superconducting tunnel junction device at the increased amount of contact overdrive; and skip the in situ resistance measurement to measure the junction resistance of the target superconducting tunnel junction device, in response to the control unit determining that the contact between the electrical probes and the contact pads of the target superconducting tunnel junction device is still not stable after a total amount of contact overdrive has reached a specified maximum amount of contact overdrive.

In another exemplary embodiment, as may be combined with the preceding paragraphs, the control unit control unit is configured to cause the prober unit to perform a probe cleaning process to clean the electrical probes in response to at least one of: an expiration of a specified time interval subsequent to a previous probe cleaning process; and upon an occurrence of a specified number of successive failed attempts to make an acceptable contact between the electrical probes and contact pads of respective superconducting tunnel junction devices for the specified number of attempted in situ resistance measurements of the respective superconducting tunnel junction devices.

Another exemplary embodiment includes a method which comprises: making contact between electrical probes of a prober unit and contact pads of a target device; incrementing a contact overdrive by a specified amount to increase a contact pressure between the electrical probes and the contact pads of the target device; measuring a contact resistance between the electrical probes and the contact pads of the target device, subsequent to incrementing the contact overdrive; comparing the measured contact resistance with a contact resistance threshold; and determining whether to perform an electrical characterization measurement of the target device, based on a result of comparing the measured contact resistance with the contact resistance threshold.

Other embodiments will be described in the following detailed description of exemplary embodiments, which is to be read in conjunction with the accompanying figures.

### BRIEF DESCRIPTION OF THE DRAWINGS

FIG. 1 schematically illustrates a laser annealing system, according to an exemplary embodiment of the disclosure.

FIG. 2 schematically illustrates a laser annealing apparatus comprising a modular optical scope unit, according to an exemplary embodiment of the disclosure.

FIG. 3 is a perspective view of a modular optical scope unit, according to an exemplary embodiment of the disclosure.

FIG. 4 schematically illustrates a laser annealing system, according to another exemplary embodiment of the disclosure.

FIG. 5A schematically illustrates a process for aligning contact probes to a Josephson junction of a quantum bit to perform a resistance measurement, according to an exemplary embodiment of the disclosure.

FIG. 5B schematically illustrates a process for aligning contact probes to a device under test to perform a resistance measurement, according to an exemplary embodiment of the disclosure.

FIG. 5C illustrates a flow diagram of a method for initializing a laser annealing system, according to an exemplary embodiment of the disclosure.

FIG. 6A illustrates a flow diagram of a calibration process for generating and utilizing contact calibration data to determine a maximum contact overdrive threshold value, according to an exemplary embodiment of the disclosure.

FIG. 6B graphically illustrates contact calibration data that is generated and utilized by the calibration process of FIG. 6A to determine a maximum contact overdrive threshold value, according to an exemplary embodiment of the disclosure.

FIG. 7A illustrates a flow diagram of a method for performing probe contact checks in conjunction with performing electrical characterization measurements of a plurality of devices, according to an exemplary embodiment of the disclosure.

FIG. 7B illustrates a flow diagram of a method for focusing and aligning to a target device for performing an electrical characterization measurement, according to an exemplary embodiment of the disclosure.

FIG. 7C illustrates a flow diagram of a method for performing a contact stability check operation, according to an exemplary embodiment of the disclosure.

FIG. 8A illustrates a flow diagram of a method for performing probe contact checks in conjunction with performing electrical characterization measurements of a plurality of devices, according to another exemplary embodiment of the disclosure.

FIG. 8B illustrates a flow diagram of method for performing an automated probe cleaning process, according to an exemplary embodiment of the disclosure.

FIG. 9A illustrates a flow diagram of a method for performing an iterative laser annealing process to progressively shift junction resistances of Josephson junctions to respective target junction resistances, according to an exemplary embodiment of the disclosure.

FIG. 9B illustrates a flow diagram of a method for focusing and aligning to a target Josephson junction for the purpose of performing an in situ Josephson junction resistance measurement, according to an exemplary embodiment of the disclosure.

FIG. 9C illustrates a flow diagram of a method for focusing and aligning to a target Josephson junction for the purpose of performing a laser anneal process, according to an exemplary embodiment of the disclosure.

FIG. 9D schematically illustrates a process for aligning a laser beam spot pattern to a Josephson junction of a quantum bit, according to an exemplary embodiment of the disclosure.

FIG. 10 schematically illustrates an exemplary architecture of a computing environment for implementing a control system that is configured to control a laser annealing system for tuning Josephson junctions, according to an exemplary embodiment of the disclosure.

### DETAILED DESCRIPTION

Exemplary embodiments of the disclosure will now be described in further detail with regard to techniques for performing electrical characterization measurements of devices using an electrical characterization system (e.g., a prober unit) that is configured to perform contact quality check operations to initialize and enable non-destructive electrical probing with low contact resistance and stable contacts between electrical probes and test pads of the devices to be characterized. As explained in further detail blow, the contact quality check operations utilize active feedback with, for example, a prober unit which allows improved contact by using adaptive force sensing protocols to increase a contact pressure between electrical probes and sample surface until a specified contact quality threshold is attained.

In some embodiments, techniques to perform contact quality check operations for reliable electrical probing are utilized in conjunction with performing in situ resistance measurements to measure junction resistances of superconducting tunnel junction devices (e.g., Josephson junctions of superconducting qubits) as part of an iterative laser annealing process for progressively tuning the junction resistance of superconducting tunnel junction devices to respective target junction resistances. It is to be noted that reliable resistance probing can be challenging in various applications, such as performing in situ resistance measurements in conjunction with an iterative laser tuning process (e.g., iterative LASIQ process) for laser tuning junction resistance of Josephson junctions. For example, with a LASIQ process, depending on the size of a given qubit lattice (e.g., number of qubits), a laser tuning process can require thousands of probing iterations for a single tuning run for tuning the transition frequencies of the qubits in the given lattice according to specified tuning plan. In this regard, when performing in situ resistance measurements to measure the junction resistances of the Josephson junction of the qubit to track the tuning progression, poor contact (e.g., high contact resistance, intermittent contact, etc.) between the electrical probes and the contact pads for measuring the junction resistance of Josephson junctions can cause, e.g., imprecise measurements, or damage to the Josephson junction, and other undesirable results, etc.

For example, poor contact between the electrical probes and the contact pads of the devices to be measured is likely to occur during long tuning runs where, for example, the electrical characterization system (e.g., prober unit) of the laser annealing apparatus thermally drifts slightly in the z-axis (e.g., deviates from a calibrated position), or where the contact surfaces of the contact pads comprise materials that tend to oxidize. In addition, when the electrical probes are applying test signals to a given device being measured, intermittent contact between the electrical probes and the contact pads of the given device can result in, e.g., voltage spikes that may damage the given device (e.g., short a Josephson junction). Also, with successive resistance measurements, the tips of the electrical probes can become gummed up and contaminated after multiple successive contact landings, resulting in a progressively poorer electrical contact as the tuning run progresses. Conventional techniques for achieving good electrical contact over a long period of time rely on blindly applying a relatively large amount of overdrive force (e.g., overdriving Z position by 40 to 50 microns) to make good electrical contact between the electrical probes and the contact pads, but such blind overdriving will cause the electrical probes to degrade over time.

Advantageously, as explained in further detail below, exemplary embodiments of the disclosure implement adaptive methods for probe overdriving wherein the overdriving is performed in an incremental manner in which the amount of contact overdrive (or prober overdrive) is performed in successive increments (e.g., 2-micron increments) to reach a minimal amount of contact overdrive which is sufficient to a achieve a good quality electrical contact before performing a resistance measurement. In other words, such minimal contact overdrive utilizes adaptive force sensing to apply the minimum possible contact force on the probes that enable non-destructive and accurate resistance measurements.

In addition, the landing zone of the probes are safely determined prior to contact. Typically, in fixed-frequency transmon qubits, a large capacitor shunts the Josephson junction, and the capacitor pads are used as contact pads to measure the Josephson junction resistance. In the case where safe landing zones are not adequately ensured, and where there exists an excess offset from the optimal landing position, the probes may land and deflect near the edges of the contact pads, or upon contact, deflect past the edges of the contact pads. Such cases may result in deleterious effects on qubit performance, given that the probing marks and subsequent deformation of the edges of the capacitor pads may interfere with the intended electromagnetic field profile.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

Further, the term “quantum chip” as used herein is meant to broadly refer to any device which comprises qubits and possibly other quantum devices. For example, a quantum chip can be semiconductor die which comprises an array (lattice) of qubits, which is fabricated on a wafer comprising multiple dies, and which can be diced (cut) from the wafer using a die singulation process to provide a singulated die. In some instances, a quantum chip can be a wafer with multiple semiconductor die. In the context of quantum computing, a quantum chip may comprise one or more processors for a quantum computer.

Moreover, the term “shot” as used herein denotes a laser anneal operation that is performed by applying laser power to a target element (e.g., Josephson junction) for a specified duration (anneal time) to tune the target element. In the context of exemplary embodiments of the disclosure as discussed herein, laser tuning methods are provided to tune junction resistances of Josephson junctions in a progressive and incremental manner wherein multiple “shots” are applied to a given Josephson junction to tune the junction resistance of the Josephson junction to a target junction resistance, which is to be contrasted with conventional approaches that tune a Josephson junction to a target junction resistance using only one laser shot.

The term “iterate” or “iteratively” used herein and in the context of a laser annealing process is meant to refer to the process which comprises a single “shot” along with associated control, measurement and computation by a LASIQ computer system and apparatus to determine a target anneal time and power for performing the anneal shot. A laser annealing iteration, or LASIQ iteration, therefore refers to the entire process by which a Josephson junction is measured, the anneal power and time is determined, and the anneal shot is performed. In this sense, a single iteration involves an entire sequence of the laser annealing system and apparatus as it pertains to one step of a progressive approach to a resistance target for one Josephson junction. The tuning of one junction to completion (i.e., reaching its target resistance) may therefore be said to progress “iteratively.” The term “iterative process” as used herein, is meant to generally refer to a set of iterations, as applicable to one or more qubits, or the like, comprising Josephson junctions, whereby the one or more qubits are tuned with the purpose of approaching their respective targets.

The term “progressive” or “progressively” as used herein and in the context of a laser annealing process, is meant to refer to the gradual approach of shifting a junction resistance of a Josephson junction to a respective target resistance. Such a progressive approach is a result of multiple annealing iterations, each of which include a laser shot to alter the junction resistance in the desired direction towards the target resistance. Additionally, such a progressive approach is asymptotic, in the sense that the tuning rate nominally decreases as the junction resistance of a given Josephson junction approaches nearer to its respective target resistance.

The term “adaptive” or “adaptively” as used herein and in the context of a laser annealing process, is meant to refer to the appropriate selection of laser annealing parameters, including such parameters as laser annealing time and annealing power, as it pertains to a laser shot, to allow the Josephson junction resistances to monotonically and asymptotically approach their respective resistance targets. The adaptive nature of the laser annealing iterations is achieved using methods described herein, whereby the laser anneal time and power are selected based on historical reconstruction of the tuning progression of the specific junction. The methods described herein account for the rate of historical tuning of the specific junction being tuned, thereby mitigating the risk of missing resistance targets (e.g., by using laser shots that have excess time such that the junction resistance is tuned beyond the desired resistance target).

The term “round-robin” as used herein and in the context of a laser annealing process for tuning the Josephson junctions of qubits, is meant to refer to a tuning process in which the Josephson junctions of, e.g., all qubits on a multi-qubit device undergo the laser annealing process in succession, and which may be followed by another round-robin or multiple round-robins in succession. Such round-robins may be continuously performed until all qubits on the multi-qubit device reach their respective targets. For example, a singulated quantum chip may comprise a number of qubit devices (e.g., 100 qubits, denoted Q1, Q2, Q3, . . . , Q100) comprising Josephson junctions. In an exemplary embodiment of a tuning method, Q1 will first be tuned with one or more annealing iterations, as desired. The process will proceed to Q2, where one or more annealing iterations may be performed, as desired. The process will then proceed to Q3, etc., until finally Q100 is tuned with one or more annealing iterations, as desired. The entire process from Q1 to Q100 is defined as one round-robin. After this first round-robin, the process may return to Q1, and will repeat again until Q100 is reached. The process of successive round-robins may provide a means of time control and delay between iterations or sets of iterations, such that the Josephson junctions may be permitted to relax to their final junction resistances prior to the next annealing iteration or set of iterations.

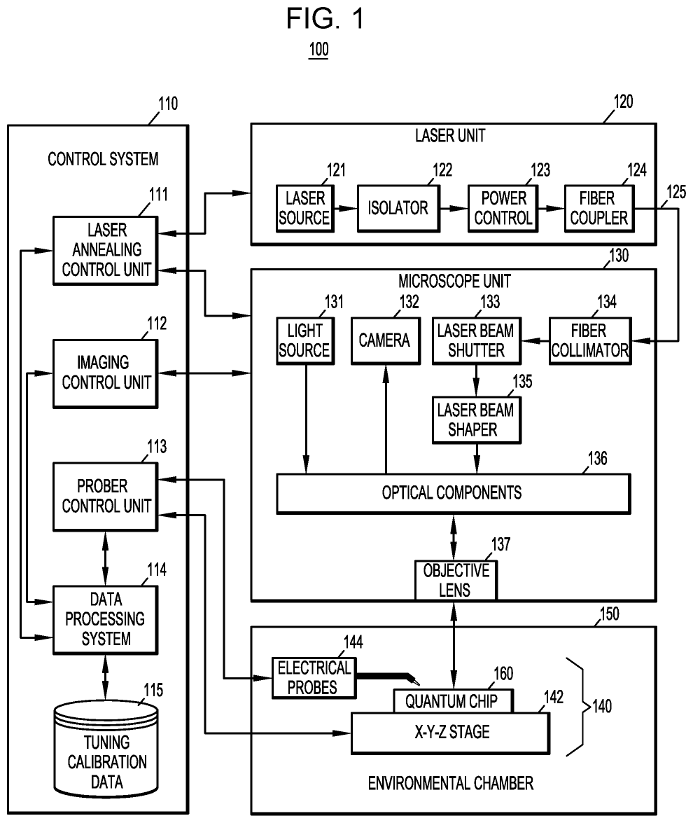

FIG. 1 schematically illustrates a laser annealing system 100 for tuning Josephson junctions, according to an exemplary embodiment of the disclosure. In some embodiments, the laser annealing system 100 is configured to implement LASIQ (Laser Annealing of Stochastically Impaired Qubits) tuning methods for laser annealing of Josephson junctions of qubits, post-fabrication, to adjust and stabilize the junction resistances R_{J} and thereby selectively tune the individual qubit frequencies via laser thermal annealing of the respective Josephson junctions. As schematically shown in FIG. 1, the laser annealing system 100 comprises a control system 110, a laser unit 120, an optical fiber 125, a microscope unit 130, a prober unit 140, and optional environmental chamber 150.

The control system 110 comprises a laser annealing control unit 111, an imaging control unit 112, a prober control unit 113, a data processing system 114, and a database of tuning calibration data 115. The laser unit 120 comprises a laser source 121, an isolator 122, a laser power control block 123, and a fiber coupler 124. The microscope unit 130 comprises a light source 131, a camera 132, a laser beam shutter 133, a fiber collimator 134, a laser beam shaper 135, a plurality of optical components 136, and an objective lens 137. The prober unit 140 comprises an X-Y-Z stage 142, and electrical probes 144. A quantum chip 160 (or any other similar device under test) can be mounted to the X-Y-Z stage. In some embodiments, the quantum chip comprises a lattice of superconducting qubits, where each superconducting qubit comprises at least one respective Josephson junction which can be annealed using the laser annealing system 100 to tune the junction resistance and, thus, tune the transition frequency of the superconducting qubit, post-fabrication.

In some embodiments, the laser unit 120 and the microscope unit 130 comprise modular units that are coupled together via the optical fiber 125. In some embodiments, the optical fiber 125 comprises a single-mode (SM) polarization-maintaining (PM) optical fiber, which is configured to preserve a linear polarization of linearly polarized light that is injected into the optical fiber 125 by the laser unit 120 and propagated to the microscope unit 130. The microscope unit 130 comprises a modular optical unit which comprises visible light and laser optical components. The microscope unit 130 can be integrated onto the prober unit 140 (e.g., a wafer-scale prober). In this regard, in some embodiments, the laser unit 120, the microscope unit 130, and the prober unit 140 can be physically coupled/attached to each other to form an integrated laser annealing apparatus which is configured to perform laser anneal operations for tuning junction resistances of Josephson junctions, as well as performing in situ junction resistance measurements, under the control of the control system 110. In some embodiments, the control system 110 is operatively/communicatively coupled to the laser unit 120, the microscope unit 130, and the prober unit 140 via wires and/or wirelessly. The control system 110 comprises hardware and/or software for automated control of various operations of the laser unit 120, the microscope unit 130, and the prober unit 140 of the laser annealing system 100.

The laser unit 120 is configured to generate a laser beam that is used by the microscope unit 130 to generate a laser beam pattern which comprises a single or multi-spot beam pattern for laser annealing a given Josephson junction. In some embodiments, the laser source 121 comprises a solid-state diode pump to generate laser energy, and a laser head to generate a focused laser beam from the laser energy emitted from the solid-state diode pump. In some embodiments, the diode pump comprises a 532 nanometer (nm) (frequency doubled) diode-pumped solid-state laser (e.g., a second harmonic generation (SHG) laser). In some embodiments, the power level of the laser source 121 (e.g., solid-state diode pump) can be adjusted by the control system 110. For example, the power level of the laser source 121 can be set to one of a plurality of different power level settings (e.g., lower power, medium power, high power settings). The isolator 122 is configured to provide polarization cleanup and optical isolation to mitigate unwanted feedback to the laser head of the laser source 121.

The laser power control block 123 is configured to actively control and calibrate the power of the focused laser beam. For example, in some embodiments, the laser power control block 123 comprises a half-wave plate, and a polarizing beam-splitter (PBS) coupled to a dump. Th half-wave plate is configured to shift the polarization direction of the laser beam output from the isolator 122. The laser power control block 123 further comprises a power monitor which comprises, e.g., an optical wedge that is configured to divert some laser beam power to a silicon photodiode. The silicon photodiode generates an electrical signal that is indicative of the laser power level, and the electrical signal is feedback to the control system 110 (e.g., the laser annealing control unit 111), the control system 110 generates control signals that are applied to the laser power control block 123 to adjustably control the laser power, as directed, for laser tuning of Josephson junctions. More specifically, in some embodiments, the power level of the laser beam can be coarsely adjusted by controlling the power output of the laser source 121, while the power level of the laser beam can be finely adjusted by operation of the laser power control block 123.

For example, in some embodiments, the half-wave plate of the laser power control block 123 is configured to shift the polarization direction of the laser beam output from the isolator 122, and the half-wave plate comprises an adjustable rotation, which can be electronically-controlled via the laser annealing control unit 111 to adjust a total attenuation by rotating the polarization incident on the polarizing beam splitter to the desired power level. In some embodiments, the polarizing beam splitter of the laser power control block 123 comprises an optical filter that allows a specific polarization of light waves associated with the laser beam to pass through the optical filter and blocks light waves of other polarizations, to thereby generate a laser beam with well-defined polarized light.

The polarized laser light generated by the laser unit 120 is coupled into the optical fiber 125 (e.g., single-mode polarizing-maintaining optical fiber) via the optical fiber coupler 124 and propagates to the microscope unit 130. In the microscope unit 130, the fiber collimator 134 (e.g., collimating lens) is configured to transform the laser light which is output from the optical fiber 125 into a free-space collimated beam. In some embodiments, the microscope unit 130 comprises a power monitor which comprises, e.g., a beam sampler (e.g., beam splitter) and photodiode, to monitor the power of the collimated laser beam to enable precise exposure control downstream from the power control/adjustment mechanisms provided by the laser unit 120.

Furthermore, in the microscope unit 130, the laser beam shutter 133 comprises an electronic shutter that is operated under control of, e.g., the laser annealing control unit 111 of the control system 110, to control the time duration of laser exposure when annealing a given Josephson junction. For example, the laser beam shutter 133 can be opened for a given duration of time when annealing a target Josephson junction to allow annealing laser beams to be projected onto the quantum chip 160 in proximity to the target Josephson junction, and then automatically close after the given duration of time. In this regard, the laser power level and the pulse duration (laser exposure) can be controlled to achieve a desired change (e.g., decrease) in the resistance of the annealed Josephson junction.

The laser beam shaper 135 is configured to split the collimated laser beam (which passes through the laser beam shutter 133) into two or more laser beams with slightly different angles relative to one another. In some embodiments, the laser beam shaper 135 comprises a diffractive optical element (DOE), such as a diffractive beam splitter which splits a single laser beam into several beams (diffraction orders) in a predefined configuration. The diffractive beam splitter comprises a holographic optical element that imparts a precise angle (e.g., a 0.5 degree shift) to the incoming laser beam in plus and minus angular directions relative to a reference plane, to thereby generate a plurality of outgoing laser beams.

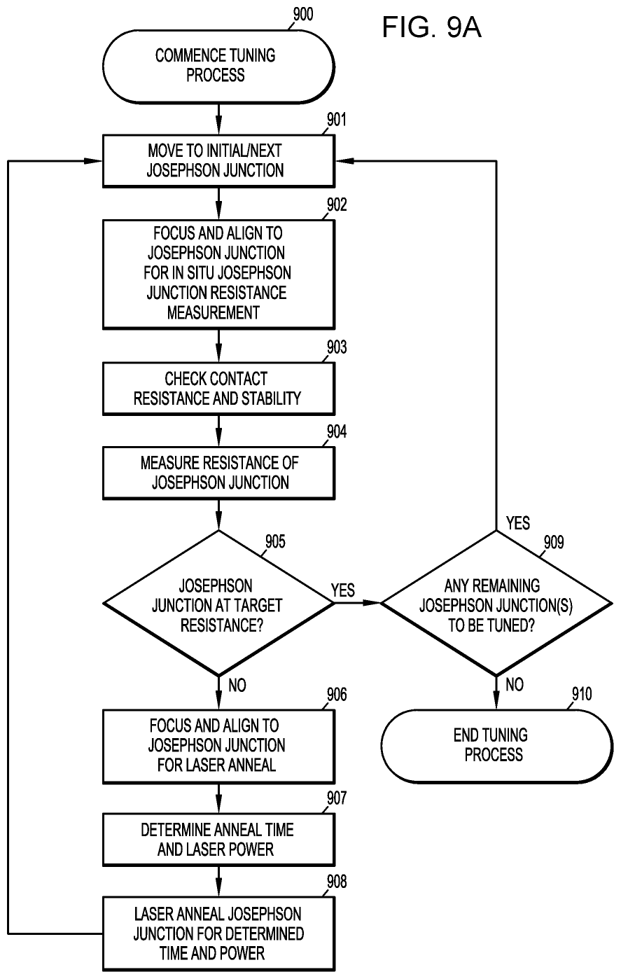

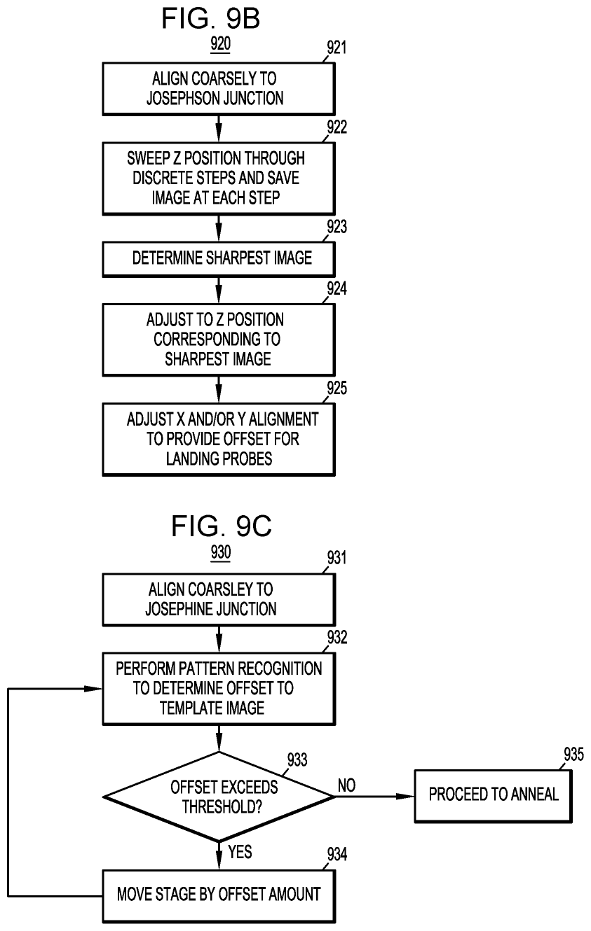

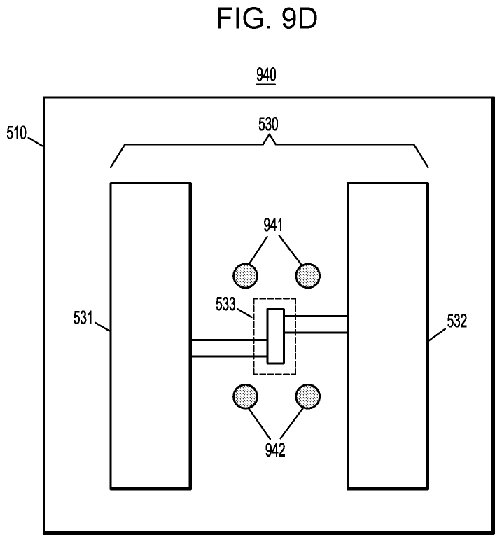

The number of laser beams generated by the laser beam shaper 135 can vary depending on the given application. For example, in some embodiments, laser beam shaper 135 comprises a 2-by-2 diffractive beam splitter, which splits the single collimated laser beam into four separate laser beams, which results in a final quad-spot illumination pattern that is projected onto the surface of the quantum chip 160 at a target location, an exemplary embodiment of which will be discussed below in conjunction with FIG. 9D. In some embodiments, the laser beam shaper 135 can be switched either manually or automatically with a different diffractive beam splitter (e.g., a plurality of DOEs on a rotary stage) to obtain a different laser spot pattern, as desired. In this regard, different diffractive beam splitters can be selected for use to generate any desired number (e.g., 2, 3, 5, 6, etc.) of laser beams with defined illumination patterns tailored to different applications.

The microscope unit 130 implements the light source 131 and the camera 132 for illuminating and viewing target features (e.g., qubits and corresponding Josephson junctions) on the surface of the quantum chip 160 within a given field of view (FOV) of the microscope unit 130. In some embodiments, the light source 131 comprises any suitable light generating device including one or more light emitting diodes (LEDs) with desired photonic wavelengths, a monochromatic light source, etc. The light source 131 together with some of the optical components 136 in the optical viewing path implement Kohler illumination to create uniform illumination of the target features in the FOV of the microscope unit 130 and to ensure that an image of the light source 131 is not visible in the resulting images captured by the camera 132.

In some embodiments, the camera 132 comprises a charge-coupled device (CCD) image sensor, or an infrared (IR) complementary metal oxide semiconductor (CMOS) image sensor. The camera 132 is utilized to capture images of a target region on the surface of the quantum chip 160 to facilitate, e.g., aligning the electrical probes 144 to contact electrodes when performing in situ Josephson junction resistance measurements, aligning the laser beam pattern onto the target region when performing laser annealing operations, etc. For example, in some embodiments, the Josephson junction of a given qubit is aligned to the center of the FOV of the microscope unit 130 using pattern recognition to, e.g., a Josephson junction template image. Also, in some embodiments, more than one camera may be used in parallel, by splitting the image path using a beam splitter and using, for example, an IR CMOS camera in addition to a visible wavelength camera, which may be used for process monitoring (e.g., a wide FOV for inspection, process tracking, or the like).

The optical components 136 include various types of optical components for directing, reflecting, focusing, modifying, and shaping, etc., the optical signals (e.g., laser beams for annealing, and visible light/IR light for viewing) as needed for the given application. For example, the optical components 136 include components such as a mirror, beam splitters, filters, polarizers, and various lenses such as a tube lens, an objective lens, relay lenses, etc.). The objective lens 137 is the lens that is located closest to the device under test (quantum chip 160) and serves to provide the base magnification for generating a magnified image that is viewed by the camera 132, and to project the annealing laser beam pattern (e.g., quad-spot pattern) onto the surface of the quantum chip 160. In some embodiments, the objective lens 137 comprises a long working distance (WD) objective lens. In an exemplary non-limiting embodiment, the objective lens 137 (together with an optional second objective lens) is configured to condense the laser beams and multi-spot pattern by 4×, while providing 20× image magnification.

The prober unit 140 is configured to automatically move the position of the quantum chip 160 during a laser annealing process to align a target Josephson junction of a given qubit within the FOV of the microscope unit 130 to perform an in situ Josephson junction resistance measurement and a laser anneal of the target Josephson junction. In particular, the quantum chip 160 is mounted to the automated X-Y-Z stage 142 which is controllably moved in three dimensions to align features of the quantum chip 160 within the FOV of the microscope unit 130 and enable contact between the electrical probes 144 and contact pads on the quantum chip 160. For example, in some embodiments, during a laser anneal process, a target Josephson junction of a given qubit is aligned to the center of the FOV of the microscope unit 130 using an automated pattern recognition process in which features of an image captured by the camera 132 are automatically aligned to corresponding features of a template image to ensure proper positioning of the target Josephson junction and associated contact pads. In particular, an alignment process is performed to ensure accurate registration between the contact pads of the target Josephson junction and the electrical probes 144 when performing an in situ Josephson junction resistance measurement. In addition, an alignment process is performed to ensure a proper alignment of the target Josephson junction and a laser spot pattern when performing a laser anneal operation.

As noted above, the electrical probes 144 are implemented to perform in situ Josephson junction resistance measurements during a laser anneal process. In particular, in situ Josephson junction resistance measurements are performed in between laser annealing operations (shots) to track the tuning progress of the Josephson junctions of the qubits during a multi-step (i.e., iterative) anneal process in which the Josephson junctions are progressively tuned. In some embodiments, the electrical probes 144 comprise two pairs of probes, which are configured to perform a 4-wire resistance measurement (or Kelvin resistance measurement) to more precisely measure the junction resistance of a Josephson junction. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I.

In some embodiments, the electrical probes 144 comprise a probe card that is mechanically mounted in a fixed position to the prober unit 140. In some embodiments, the integration of the microscope unit 130 and the prober unit 140 is configured to ensure that a sample imaging plane and a laser focal plane are substantially identical, while a probing plane is displaced from the sample imaging plane by a present amount, e.g., 70 microns, 80 microns, etc. In this configuration, the electrical probes 144 are fixedly displaced from the image plane, and the Z position of the X-Y-Z stage 142 (with the quantum chip 160 mounted thereon) is moved into a default contact position to make electrical contact between the electrical probes 144 and target contact pads on the quantum chip 160, to perform an in situ Josephson junction resistance measurement. In some embodiments, the microscope unit 130 may also be mounted on its own X-Y-Z stage and may be additionally moved with those corresponding X, Y, and Z degrees of freedom.

In some embodiments, in order to image, electrically characterize, and anneal Josephson junctions, the X-Y-Z stage 142 is set at various specified positions such that these functions may be safely and effectively performed. For example, in some embodiments, the specified positions include a “contact position,” an “anneal position,” and a “safety position”, which denote various positions of the X-Y-Z stage 142. In particular, the terms “contact position” or “initial default contact position” as used herein, and in the context of laser annealing system 100, refers to the position of the X-Y-Z stage 142 such that the sample (i.e., quantum chip 160) is in mechanical and electrical contact with the probes. That is to say, the surface of the sample is substantially identical to the probing plane. In this “contact position” configuration, electrical characterization may take place, which typically involves a 4-wire (Kelvin) resistance measurement. Each annealing iteration will typically involve a junction resistance measurement, where the X-Y-Z stage 142 is brought into the “contact position” prior to subsequent annealing.

The term “anneal position,” as used herein and in the context of laser annealing system 100, is meant to refer to the Z position of the X-Y-Z stage 142 such that the surface of the sample (i.e., quantum chip 160) is at the focal plane of the laser annealing beam. In an exemplary embodiment, at the “anneal position,” the surface of the sample (i.e., quantum chip 160) is substantially identical to the imaging plane, such that both imaging and annealing occurs at the same Z position of the X-Y-Z stage 142, or stated equivalently, the sample and laser beam may be both viewed in focus simultaneously by the imaging system. Additionally, at the “anneal position,” pattern recognition and corrective alignment may take place, such that the junction is correctly centered at the FOV prior to annealing. It is also at the anneal position which visual characterization, inspection, and the like, may be performed to determine whether the chip is physically suitable for use as a chip candidate. Nominally, the “anneal position” may be chosen to be a fixed difference from the default “contact position,” which is herein defined as the “separation distance,” which may be, for example, 70 microns, 80 microns, etc., and may be selected by the operator as desired.

The term “separation distance,” as used herein and in the context of laser annealing system 100, is meant to refer to the relative separation between the “contact position” and “anneal position.” In some embodiments, the “separation distance” is selected as a fixed value, for example, 70 microns, whereupon the X-Y-Z stage 142, when in the “contact position,” may displace away in the Z position from the probe plane, such that the sample surface will subsequently be in the “anneal position” whereupon both laser annealing and sample imaging may occur. Similarly, once imaging and annealing is completed, the Z position of the X-Y-Z stage 142 may be incremented the “separation distance” (e.g., 70 microns) such that the probe tips are in contact with the contact pads and electrical characterization may occur.

The term “safety position,” as used herein and in the context of laser annealing system 100, is meant to refer to a large displacement of the Z position of the X-Y-Z stage 142 such that the surface of the sample (i.e., quantum chip 160) is safely displaced from the “contact position” such that the tallest surface feature of the sample will not cross the probing plane, or stated equivalently, no feature on the sample intersects the probing plane. In this way, regardless of the X-position or Y-position that is chosen on the sample, the probes suffer no risk of damage due to impact with any surface feature while the X-Y-Z stage 142 is in the “safety position.”

In an exemplary embodiment, the position of the probe card is fixed in the Z position, and the “separation distance” is selected to be 70 microns, that is, the “anneal position” is 70 microns below the “contact position.” Additionally, the “safety position” may be chosen (for example) to be 1000 microns or larger, or a value that is sufficiently larger than the height of any feature on the sample.

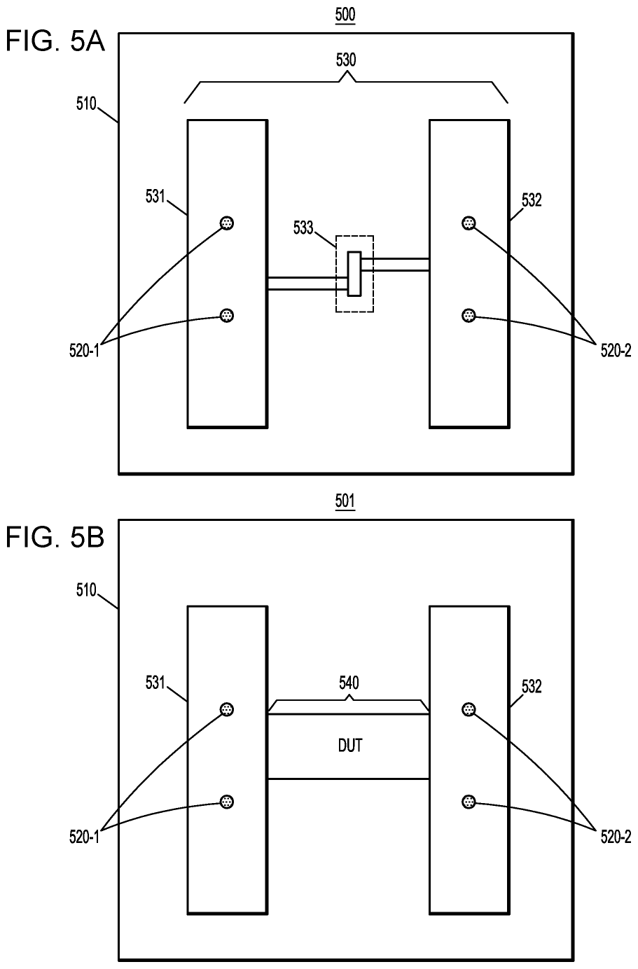

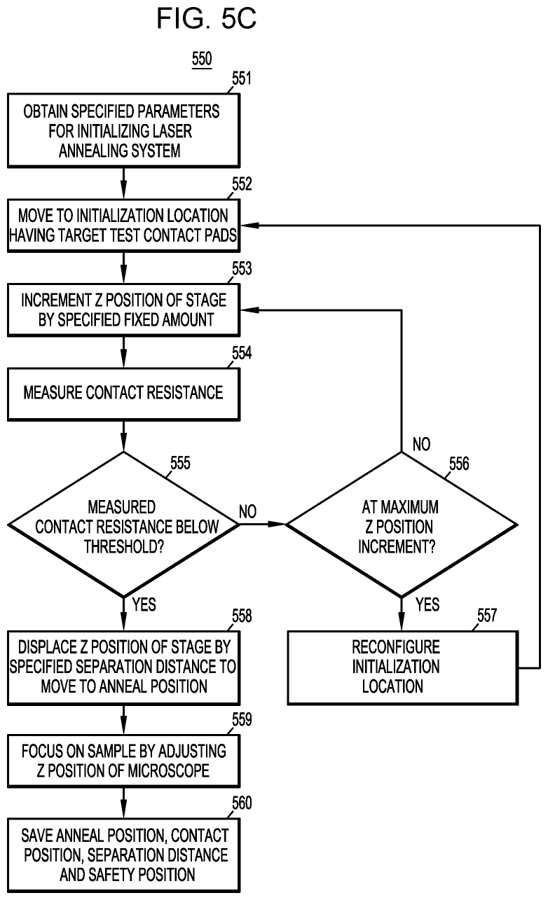

Prior to performing resistance measurements or laser annealing operations on a quantum chip, an initialization process is performed to initialize the laser annealing system 100 to known relative positions of the sample plane, the probing plane, imaging plane and laser annealing plane, as such relative positions are not known a priori. Without performing an initialization process, any operation (resistance measurement, laser annealing) performed using the laser annealing system 100 may exhibit, for example, image defocusing, poor electrical contact during probing, and/or poor annealing performance. Therefore, an initialization protocol must be performed to ensure that the contact position, anneal position, and safety position is well defined, which is referred to herein as an “annealing initialization” process. In an exemplary embodiment of an annealing initialization process, the X-Y-Z stage 142 may be programmed to move to a safe location, either on a test chip, an initialization chip, or the like, where a clean conducting surface (e.g., contact pads) is available under the probes. In some embodiments, a dedicated initialization chip with an array of conducting contact pads is available to safely contact the electrical probes 144. The X-Y-Z stage 142 is subsequently incremented (e.g., in 2-micron increments) in the Z position, towards the electrical probes 144, and the contact resistance is checked for each increment until a contact threshold is realized (e.g., 100 ohms, or another threshold as desired), which indicates successful contact between the sample and the probing plane, or equivalently, the sample plane and probing plane are co-located, and the X-Y-Z stage 142 is in the “contact position.” Subsequent to determining the contact position, the X-Y-Z stage 142 is lowered in the Z position by the desired 70 microns “separation distance,” such that the X-Y-Z stage 142 is in the “anneal position.” However, it may be the case that the image focal plane is not yet substantially co-located with the laser annealing plane. In this case, the microscope unit may be adjusted, either manually using a Z position adjustment to adjust the focal plane, or automatically (in the case where the microscope is mounted on its own automated X-Y-Z stage, and controlled by the imaging control unit 112), such that the imaging focal plane is substantially co-located with the sample plane, and the sample is in focus while the X-Y-Z stage 142 is in the “anneal position.” Using this protocol, the “anneal position” thus corresponds to the sample surface being in focus in the microscope unit 130, and both imaging and annealing may now occur at the “anneal position.” In the case where electrical measurement is desired, reliable probing may subsequently be implemented by simply incrementing the Z position of the X-Y-Z stage 142 by 70 microns (i.e., the “separation distance”), or more, as some level of overdrive is desirable for robust electrical contact. Furthermore, a “safety position” may be defined, such that when moving between qubits, or other features on the quantum chip 160, the X-Y-Z stage 142 first moves to its safety position, then moves to the X and Y-position of the desired feature, then moves to either the “anneal position” for imaging/tuning, or to the “contact position” for electrical characterization. This annealing initialization protocol (an exemplary embodiment of which is described below in conjunction with FIG. 5C) may be generally implemented to ensure that stage motion, imaging, annealing, and electrical measurement may be safely and reliably performed. It is to be understood that in one or more embodiments, the annealing initialization protocol, as well as the various X-Y-Z stage 142 positions, are actively used in the operation and calibration of laser annealing system 100. In some embodiments, the laser focal plane may be engineered as an additional degree of freedom relative to the image focal plane, and the laser beam may be focused or defocused as desired.

In an exemplary embodiment, the contact position, the anneal position, the separation distance, and the safety position of the prober unit 140 may be used in conjunction with the microscope unit 130 to perform annealing iterations. For example, prior to a laser anneal iteration, the resistance of a Josephson junction may be measured by moving the X-Y-Z stage 142 into the contact position, whereupon the probes are in physical and electrical contact with the contact (or test) pads. Once electrical characterization is complete, the X-Y-Z stage 142 is displaced by the separation distance (e.g., 70 microns), thus moving to the anneal position. At this point, image and pattern recognition may be implemented to ensure appropriate alignment to the junction, prior to performing a laser exposure as part of a laser anneal sequence. Once the anneal is complete over the desired duration of exposure, the X-Y-Z stage 142 may, in some embodiments, be moved back to the contact position to probe the Josephson junction and assess the changes to the junction resistance after annealing. In other embodiments, the X-Y-Z stage 142 may be moved to the safety position, and subsequently the X-position and Y-position of the next junction to be measured and annealed. The process for the new Josephson junction is then repeated, by performing electrical characterization at the contact position, followed by displacing by the separation distance, and then alignment and annealing at the anneal position, and so on.

In some embodiments, the prober unit 140 is housed or otherwise disposed within the optional environmental chamber 150 to control an ambient environment during laser annealing, wherein different ambient environments impact the laser annealing progression differently. For example, in some embodiments, the laser annealing system 100 may comprise an environmental gas control system which is coupled to the optional environmental chamber 150 and which is configured to inject a mixture of one or more gases into the optional environmental chamber 150 to control the annealing environment. More specifically, in some embodiments, the environmental gas control system may comprise a gas dilution unit which is connected to a plurality of gas cylinders which store different gases (e.g., nitrogen, dry air, etc.), wherein the gas dilution unit can mix different gases at various concentrations and inject the mixed gases into the optional environmental chamber 150, as desired, to provide a given gas environment for laser annealing. In addition, the environmental gas control system comprises a vacuum system coupled to the optional environmental chamber 150 to evacuate anneal gases from the chamber or otherwise evacuate air from the optional environmental chamber 150 to perform laser annealing in a vacuum atmosphere.

Moreover, in some embodiments, a temperature control system is coupled to the X-Y-Z stage 142 (e.g., wafer chuck) to control the temperature of the X-Y-Z stage 142 on which the quantum chip 160 is mounted. The X-Y-Z stage 142 may be temperature controlled to allow high-temperature anneals (e.g., bulk anneals) or low-temperature probing for low-noise electrical resistance measurements, as well as reducing the relative contribution of substrate conductivity on the junction resistance measurement. For example, in some embodiments, the X-Y-Z stage 142 can be temperature controlled in a range of −60° C. to 300° C.

As noted above, various functions of the laser unit 120, the microscope unit 130, and the prober unit 140 are automatically controlled by the control system 110. In some embodiments, the laser annealing control unit 111, the imaging control unit 112, and the prober control unit 113, comprise respective hardware interfaces for interfacing with the laser unit 120, the microscope unit 130, and the prober unit 140, as needed, to generate and apply control signals to components of such units 120, 130, and 140, and to receive and process signals (e.g., data, measurements, feedback controls signals, etc.) received from components of such units 120, 130, and 140. The data processing system 114 comprises one or more processors that execute software programs/routines to control laser annealing, imaging, and prober operations by processing data received from the control units 111, 112, and 113 (e.g., to perform automated pattern recognition for active alignments, perform junction resistance measurement computations, etc.), and generating and outputting control signals to cause the control units 111, 112, and 113, to control the operations of the laser unit 120, the microscope unit 130, and the prober unit 140 in a coordinated manner, when performing laser annealing and in situ junction resistance measurements, as discussed herein.

For example, in some embodiments, the laser annealing control unit 111 is configured to control operation of components of the laser unit 120, such as the laser source 121 and the laser power control block 123, to adjust the power level of the laser beam output from the laser unit 120. In addition, the laser annealing control unit 111 is configured to control the operation of the components of the microscope unit 130 for laser annealing operations. For example, the laser annealing control unit 111 is configured to control the operation of the laser beam shutter 133 to control the duration of laser exposure when laser tuning a given Josephson junction. Further, in some embodiments, the laser annealing control unit 111 is configured to control the laser beam shaper 135, e.g., to switch the diffractive beam splitter settings and corresponding laser illumination patterns.

Further, in some embodiments, the imaging control unit 112 is configured to control the operation of the light source 131, the camera 132, and one or more of the optical components 136 (e.g., tube lens) that make up the image path of the microscope unit 130. For example, the imaging control unit 112 can generate camera control signals to cause the camera 132 to capture images within the FOV of the microscope unit 130 and send images to the imaging control unit 112. The imaging control unit 112 can be configured to preprocess the image data into a suitable format for processing by the data processing system 114 to perform automated pattern recognition functions to perform laser alignment and electrical probe alignment operations as discussed herein.

Moreover, in some embodiments, the prober control unit 113 is configured to control operations of the prober unit 140. For example, the prober control unit 113 comprises hardware for generating test voltages that are applied to the electrical probes for performing junction resistance measurements, e.g., for a 4-wire (Kelvin) resistance measurement, the prober control unit 113 may comprise current and voltage measurement circuitry, which is coupled to the electrical probes 144, and configured to measure current that flows through a Josephson junction as a result of applying a test voltage to the electrical probes, as well as measure a voltage across the Josephson junction. The measured currents and voltages can be digitized and sent to the data processing system 114 for computing junction resistances. In addition, the prober control unit 113 comprises control elements to precisely control movement and positioning of the X-Y-Z stage 142.

In some embodiments, the voltage is sourced at a series of voltage steps or increments (e.g., from −20 millivolts to +20 millivolts, in increments of 2 millivolts) and the current is measured, and a linear regression is used to extract the slope of the I-V curve, which corresponds to the resistance of the Josephson junction. In other embodiments, the voltage is sourced at a fixed positive voltage (e.g., +20 millivolts) and subsequently at a fixed negative voltage (e.g., −20 millivolts), and this process may be repeated any number of times to perform averaging of the source voltage and measured current in the 4-wire (Kelvin) measurement, followed by taking a ratio of the average voltage and average current to yield the junction resistance. In some embodiments, the fixed positive and negative voltage source and current measurements may be performed at a higher frequency (for example, 1 kHz), and measurement may occur, for example, using demodulation at the same frequency (e.g., 1 kHz) such that the impact of 1/f noise may be significantly mitigated to improve the precision of resistance measurements. In some embodiments, measurements may be performed by sourcing current and measuring voltage across the Josephson junction using a 4-wire (Kelvin) configuration.

In some embodiments, the data processing system 114 executes a calibration process by performing laser annealing operations on Josephson junctions of representative hardware, using different combinations of laser anneal power and anneal time, to generate tuning calibration data (stored in the database of tuning calibration data 115). The tuning calibration data can be obtained by performing a calibration process on representative hardware which, in some embodiments, can be dummy Josephson junctions that reside on the same quantum chip to be tuned, and in other embodiments, can be Josephson junctions of qubits that are formed on a sister chiplet from the same fabrication process. The tuning calibration data is analyzed using statistical methods to fit the tuning calibration data to tuning curves, wherein the tuning curves are utilized to determine tuning rates and maximum tuning ranges for Josephson junctions under different laser anneal powers and anneal times. The tuning curves are utilized by the data processing system 114 to select a target combination of anneal power and annal time, as desired, for a target tuning rate and maximum tuning range for laser annealing Josephson junctions of the given quantum chip, post fabrication. In some embodiments, the tuning curves are used to predict an initial laser anneal operation (initial shot) for tuning a given Josephson junction to a certain target (e.g., 50% to target) on a first shot. The calibration process ensures a smooth and rapid approach to a tuning target resistance for a given Josephson junction, while mitigating risk of both undershooting and overshooting the tuning.

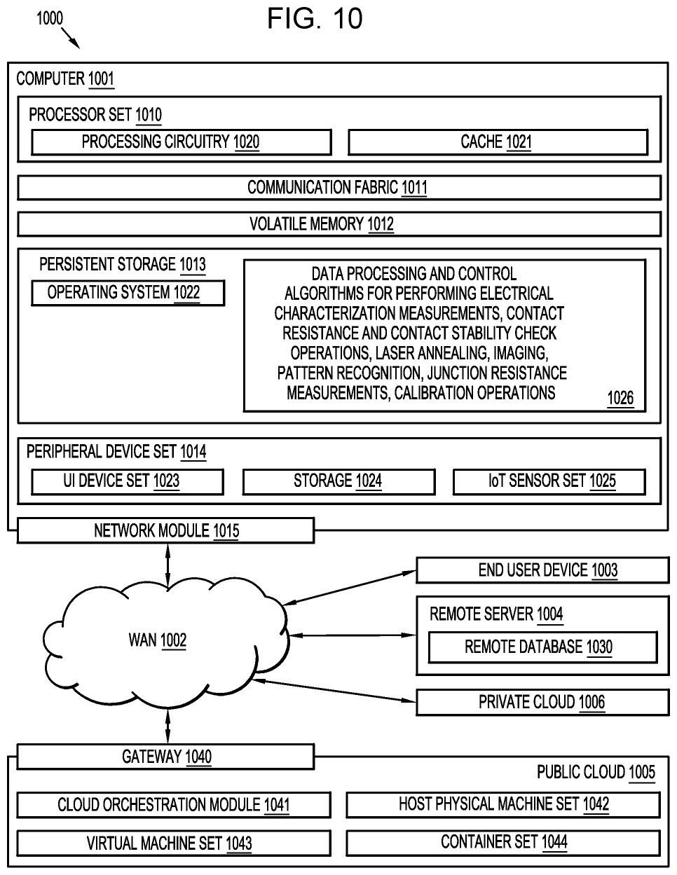

In some exemplary embodiments, the control system 110 for the laser annealing system 100 may be implemented using any suitable computing system architecture which is configured to implement methods to support the automated control processes as described herein by executing computer readable program instructions that are embodied on a computer program product which includes a computer readable storage medium (or media) having such computer readable program instructions thereon for causing a processor to perform control methods as discussed herein. An exemplary architecture of a computing environment for implementing a control system that is configured to control the exemplary laser annealing apparatus for tuning Josephson junctions as disclosed herein, will be discussed in further detail below in conjunction with FIG. 10. It is to be appreciated that the exemplary laser annealing system 100 of FIG. 1 can be used to perform exemplary laser tuning methods, such as those discussed in detail below in conjunction with, e.g., FIGS. 9A, 9B, 9C, and 9D, for tuning junction resistances of superconducting tunnel junction devices for various applications, e.g., tuning junction resistances of Josephson junctions of superconducting qubits whose transition frequencies can be tuned using LASIQ tuning operations that are based on the exemplary adaptive laser tuning techniques as discussed herein.

It is to be noted that in the exemplary laser annealing system 100 of FIG. 1, the laser unit 120 and the microscope unit 130 collectively comprise optical apparatus, and the prober unit 140 comprises an electrical characterization apparatus. The optical apparatus and electrical characterization apparatus comprise an integrated configuration of a laser annealing apparatus that is configured to perform various operations, in situ, to facilitate laser tuning of junction resistances of superconducting tunnel junction devices on a quantum chip (e.g., Josephson junctions), wherein such operations include, for example, laser annealing operations for laser tuning junction resistances of superconducting tunnel junction devices on a quantum chip, and in situ resistance measurements to measure the junction resistances of the superconducting tunnel junction devices at any time before, during, and/or after the laser annealing operations, as needed, to determine or otherwise track the progression of the junction resistance shifts of the superconducting tunnel junction devices.

In some embodiments, the electrical characterization apparatus is configured to perform direct current (DC) resistance measurement operations to measure the junction resistances of the superconducting tunnel junction devices. In some embodiments, the electrical characterization apparatus is configured to perform alternating current (AC) resistance measurement operations to measure the junction resistances of the superconducting tunnel junction devices. In some embodiments, the resistance measurements are performed using 4-wire (Kelvin) resistance measurements for more precise measurements of junction resistances. In some embodiments, the electrical characterization apparatus comprises a wafer-scale prober apparatus (e.g., 200 millimeter (mm) or 300 mm wafer-scale prober apparatus) configured to perform the integrated electrical characterization techniques and discussed herein. The wafer prober comprises at least one of an automated and semi-automated wafer probing system.

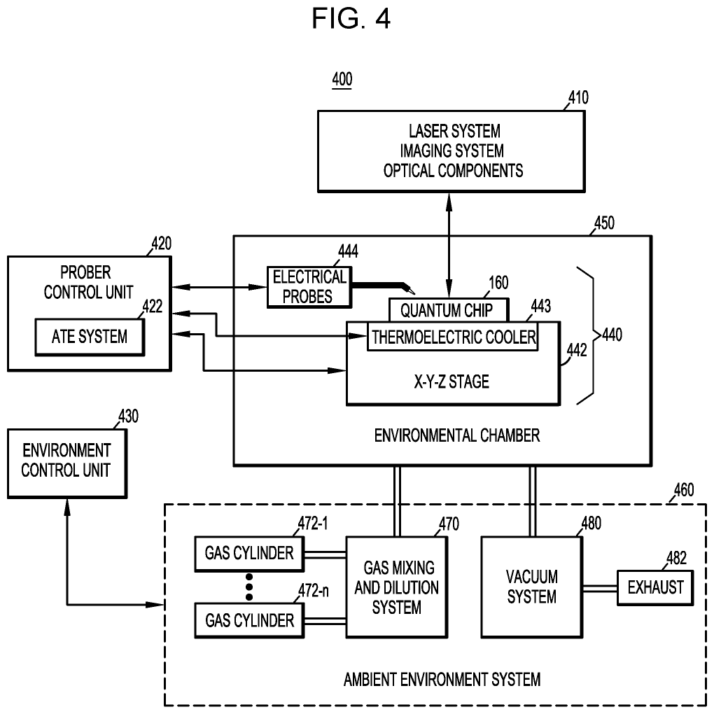

Furthermore, in some embodiments, as noted above, the electrical characterization apparatus (e.g., prober unit 140) comprises an environmental chamber (e.g., the environmental chamber 150, FIG. 1) that is configured to control an ambient environment of the quantum chip when performing the laser annealing operations. For example, the environmental chamber is configured to control the ambient environment by at least one of (i) controlling a composition of one or more gases within the environmental chamber, and (ii) generating a vacuum within the environmental chamber, as desired, when performing, e.g., laser annealing operations. Exemplary techniques for ambient environment control will be discussed in further detail below in conjunction with FIG. 4.

Moreover, in some embodiments, the electrical characterization apparatus (e.g., prober unit 14) comprises a thermal control system that is configured to at least one of (i) heat a quantum chip to perform a bulk thermal anneal operation for shifting the junction resistances of superconducting tunnel junction devices of the quantum chip, and (ii) cool the quantum chip to perform the in situ resistance measurements. Exemplary devices and techniques for implementing and utilizing thermal control will be discussed in further detail below in conjunction with, e.g., FIG. 4.

It is to be noted that FIG. 1 illustrates an exemplary laser annealing apparatus in which the optical apparatus is implemented, in part, using a modular optical scope unit (e.g., the microscope unit 130), which comprises an optically integrated configuration of an imaging unit, optical components, a laser beam shaping device, and a laser beam focusing element. In particular, the microscope unit 130 comprises a modular optical scope unit with integrated components that are configured to generate, align, and project a desired laser beam pattern at the surface of the quantum chip to perform laser anneal operations. The microscope unit 130 is “modular” in that it provides an optical scope unit which comprises a packaged functional assembly of components to perform various functions (e.g., imaging, laser beam pattern generation and delivery, etc.), and which provides portability for use with suitable configurations of the laser unit 120 and the prober unit 140. The microscope unit 130 comprises a compact and portable optical scope assembly which can be mounted on a desired prober unit, and coupled to any suitable laser unit via a single mode optical fiber 125 to receive laser beam energy from a separate laser unit. In this regard, the microscope unit 130 does not include the actual laser source and, thus, can be made more compact and portable.

In this regard, on a fundamental level, the microscope unit 130 comprises a optical microscope device which comprises an optically integrated configuration of components for performing functions such as, e.g., imaging a target device within a field of view of the optical microscope device, laser annealing the target device by generating a laser beam spot pattern from a laser beam received on an optical fiber from a remote laser source, and controlling a duration of exposure of the laser beam spot pattern for laser annealing the target device. The optical microscope device comprises a modular device which is configured for mounting to an electrical characterization system to enable in situ electrical characterization of the target device in conjunction with laser annealing, wherein in some embodiments, the electrical characterization system comprises a wafer-scale prober unit.

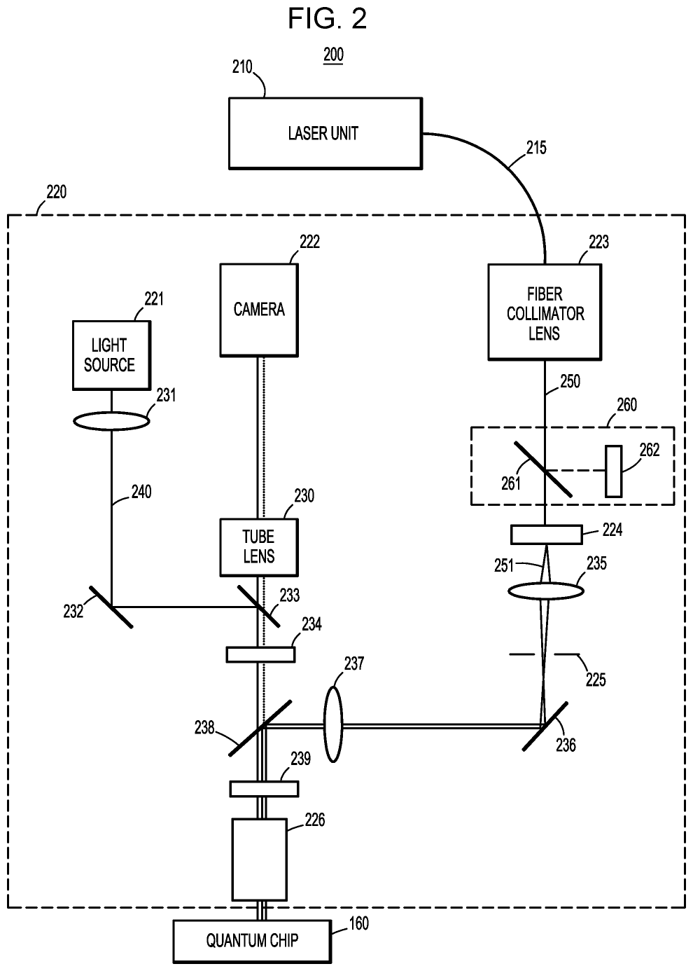

FIG. 2 schematically illustrates a laser annealing apparatus 200 comprising a modular optical scope unit, according to an exemplary embodiment of the disclosure. In particular, FIG. 2 schematically illustrates a laser annealing apparatus comprising laser unit 210, optical fiber 215, and a modular optical scope unit 220. In some embodiments, the modular optical scope unit 220 schematically illustrates an exemplary architecture for implementing the microscope unit 130 of the laser annealing apparatus in FIG. 1. The modular optical scope unit 220 comprises a light source 221, a camera 222, a fiber collimator lens 223, a laser beam shaper 224, a laser beam shutter 225, and an objective lens 226, which perform the same or similar functions as the corresponding components of the microscope unit 130 as discussed above, the details of which will not be repeated.

Further, the modular optical scope unit 220 comprises a plurality of optical components such as a lens 231, a mirror 232, a beam splitter 233, a notch filter 234, a relay lens 235, a mirror 236, a relay lens 237, a beam splitter 238, and an optional quarter-wave plate 239, which are collectively configured for directing, reflecting, focusing, modifying, and shaping, etc., the optical signals (e.g., laser beams for annealing, and visible light/IR light for viewing) as needed for the given application. In general, the tube lens 230 comprises a multi-element optical component that is configured to focus parallel light coming through the objective lens 226 onto the image plane of the focal plane array of the camera 222. The notch filter 234 is configured to filter the light using known techniques. The beam splitters 233 and 238 are optical components that are configured to split incident light at a designated ratio into two separate beams, and combine two different beams into a single beam. The relay lenses 235 and 237 are configured to relay the laser beams along the optical laser path from the laser beam shaper 224 to the objective lens 226. The optional quarter-wave plate 239 can be used to alter the polarization state of light traveling through the waveplate. For example, the optional quarter-wave plate 239 can be implemented to shift linearly polarized light into circularly polarized light, and vice versa.

In the light source path, the lens 231 is configured to “parallelize” the light emitted from the light source 221 to form an illumination beam 240. The illumination beam 240 is directed along an optical path by the mirror 232 to the beam splitter 233, through the notch filter 234, the beam splitter 238, the optional quarter-wave plate 239, and focused by the objective lens 226 to illuminate the portion of the quantum chip 160 within the FOV of the objective lens 226. The light source 221 together with the optical components 231, 232, and 233 implement a Kohler illumination configuration to create uniform illumination of the target features in the FOV of the objective lens 226, while ensuring that an image of the light source 221 is not visible in the resulting images captured by the camera 222.

In the laser beam path, the fiber collimator lens 223 collimates the laser light emitted from the optical fiber 215 to generate a collimated laser beam 250. In some embodiments, the modular optical scope unit 220 comprises a power monitor 260 which comprises, e.g., a beam sampler 261 (e.g., beam splitter) and a photodiode 262, to monitor the power of the collimated laser beam 250 to enable precise exposure control downstream from the power control/adjustment mechanisms provided by the laser unit 210. The collimated laser beam 250 propagates to the laser beam shaper 224 which, as noted above, is configured to split the collimated laser beam 250 into two or more laser beams with slightly different angles relative to one another. As noted above, the laser beam shaper 224 comprises a diffractive optical element, such as a diffractive beam splitter which splits a single laser beam into several beams (diffraction orders) in a predefined configuration.

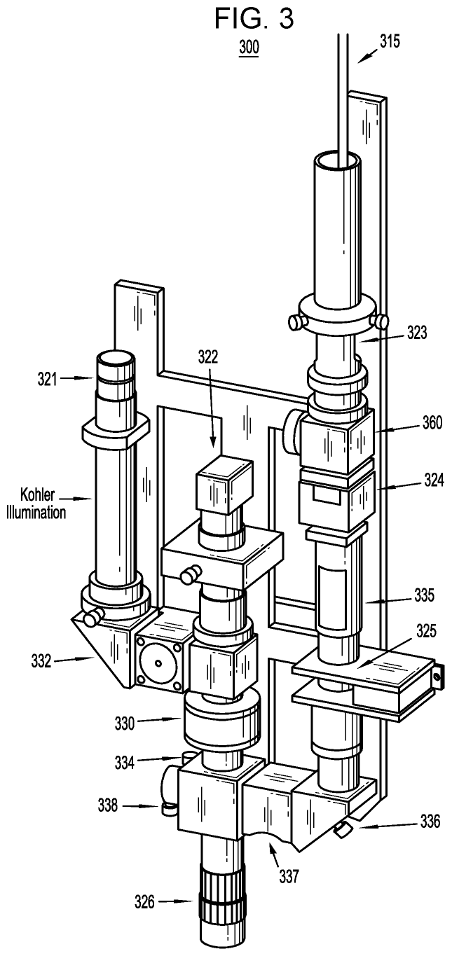

FIG. 3 is a perspective view of a modular optical scope unit, according to an exemplary embodiment of the disclosure. In particular, FIG. 3 illustrates an exemplary modular optical scope unit 300, which is based on the exemplary integrated optical assembly architecture as schematically illustrated in FIG. 2. For example, the modular optical scope unit 300 is coupled to an optical fiber 315 to receive laser energy from a remote laser unit, and the modular optical scope unit 300 comprises a light source 321, a camera 322 (imager), a fiber collimator lens 323, a laser beam shaper 324, a laser beam shutter 325, an objective lens 326, a plurality of optical components such as tube lens 330, a mirror 332, a notch filter 334, relay lenses 335 and 337, a mirror 336, a beam splitter 338, and a power monitor 360, which are collectively configured for directing, reflecting, focusing, modifying, and shaping, etc., the optical signals (e.g., laser beams for annealing, and visible light/IR light for viewing) as needed for the given application. The exemplary modular optical scope unit 300 shown in FIG. 3 comprises a portable, compact optical system that can be readily mounted on any suitable prober unit (e.g., wafer-level prober system) to integrate the optical and electrical characterization functionality of laser annealing apparatus to perform in situ laser annealing and junction resistance measurement operations to facilitate laser tuning of superconducting tunnel junction devices on a quantum chip, e.g., perform a LASIQ process to tune transition frequencies of qubit devices in a given qubit lattice of the quantum chip 160.

It is to be noted that while FIGS. 1, 2, and 3 illustrate exemplary embodiments of a laser annealing apparatus which comprises an integrated configuration of a modular optical scope and electrical characterization apparatus, in other embodiments, a laser annealing apparatus can be implemented using a discrete table-top optical apparatus in conjunction with an electrical characterization apparatus to perform laser tuning operations and associated operations as discussed herein. For example, a laser annealing system can be implemented to have a control system, an imaging unit, a laser unit, and a prober unit (e.g., electrical characterization apparatus), wherein the optical apparatus is implemented using a separate imaging unit and laser unit. The laser unit would comprise a laser source to generate a laser beam, and various laser optical components which collectively operate to generate a laser beam pattern from the laser beam generated by the laser source, project the laser beam pattern onto a target sample to perform laser annealing operations, control annealing time using an electronic shutter, etc. The imaging unit would be a separate unit that is optically coupled to the laser unit, and configured to support various operations such as real-time visualization, imaging, pattern recognition, and other related functions as discussed herein.

FIG. 4 schematically illustrates a laser annealing system, according to another exemplary embodiment of the disclosure. In particular, FIG. 4 schematically illustrates a laser annealing system 400 which comprises an optical system 410, a prober control unit 420, a prober unit 440 disposed in an environmental chamber 450, an environment control unit 430, and an ambient environment system 460. The optical system 410 comprises a laser system, imaging system and associated optical components. The optical system 410 can be implemented using any one of the exemplary optical architectures of the laser units, imaging units, and modular microscope units, as discussed above in conjunction with FIGS. 1, 2, and 3. The prober control unit 420 and the prober unit 440 comprise an exemplary embodiment of an electrical characterization system.

The prober unit 440 comprises an X-Y-Z stage 442 having a wafer chuck which comprises a thermoelectric cooler 443, and electrical probes 444. The exemplary prober unit 440 is similar in configuration and operation of the exemplary prober unit 140 discussed above in conjunction with FIG. 1, except that the prober unit 440 implements the thermoelectric cooler 443 to provide a thermal control system (e.g., temperature-controlled wafer chuck system, or other suitable types of heating/cooling systems) that is configured to (i) heat the quantum chip 160 to perform a bulk thermal anneal operation for shifting the junction resistances of the tunnel junction devices of the quantum chip 160, and (ii) cool the quantum chip 160 to perform the in situ resistance measurements, as will be discussed in further detail below. In some embodiments, a temperature-controlled wafer chuck system can be temperature controlled in a range of −60° C. to 300° C. The prober control unit 420 comprises or otherwise implements an automated test equipment (ATE) system 422 which comprises a combination of hardware and software to control automated operations of the electrical characterization system including the prober unit 440 (e.g., automated movement of probes, generating test signals, processing resulting voltage/current signals generated as a result of resistance measurement probing operations, etc.)

The prober unit 440 is housed or otherwise disposed within the environmental chamber 450 to control an ambient environment within the environmental chamber 450 by operation of the environment control unit 430 and the ambient environment system 460. The ambient environment system 460 comprises a gas mixing and dilution system 470, which comprises an environmental gas control system which is coupled to the environmental chamber 450 and which is configured to inject a mixture of one or more gases into the environmental chamber 450 to control the annealing environment. The gas mixing and dilution system 470 is connected to a plurality of gas cylinders 472-1, . . . , 472-n, which store different gases (e.g., nitrogen, dry air, etc.). The gas mixing and dilution system 470 operates under control of the environment control unit 430 to mix different gases at various concentrations and inject the mixed gases into the environmental chamber 450, as desired, to provide a given gas environment for laser annealing. In addition, the ambient environment system 460 comprises a vacuum system 480 coupled to the environmental chamber 450 to evacuate anneal gases from the environmental chamber 450 or otherwise evacuate air from the environmental chamber 450 to perform laser annealing in a vacuum atmosphere. An exhaust system 482 is coupled to the vacuum system 480, wherein the exhaust system is configured to direct the evacuated gases for proper disposal.

As noted above, reliable resistance probing can be challenging in various applications, such as performing in situ resistance measurements in conjunction with an iterative laser tuning process (e.g., iterative LASIQ process) for laser tuning junction resistance of Josephson junctions. For example, with a LASIQ process, depending on the size of a given qubit lattice (e.g., number of qubits), a laser tuning process can require thousands of probing iterations for a single tuning run for tuning the transition frequencies of the qubits in the given lattice according to specified tuning plan. In this regard, when performing in situ resistance measurements to measure the junction resistances of the Josephson junction of the qubit to track the tuning progression, poor contact (e.g., high contact resistance, intermittent contact, etc.) between the electrical probes and the contact pads for measuring the junction resistance of Josephson junctions can cause, e.g., imprecise measurements, or damage to the Josephson junction, and other undesirable results, etc.

For example, poor contact between the electrical probes and the contact pads of the devices to be measured is likely to occur during long tuning runs where, for example, the electrical characterization system (e.g., prober unit) of the laser annealing apparatus thermally drifts slightly in the z-axis (e.g., deviates from a calibrated position), or where the contact surfaces of the contact pads comprise materials that tend to oxidize, thus requiring significant additional overdrive to create good electrical contact. Such drift may similarly occur in long runs where the contact position, the anneal position, and the safety position can undergo mechanical drift after long periods, and many anneal iterations without re-initialization. In addition, when the electrical probes are applying test signals to a given device being measured, intermittent contact between the electrical probes and the contact pads of the given device can result in, e.g., voltage spikes that may damage the given device (e.g., short a Josephson junction). Also, with successive resistance measurements, the tips of the electrical probes can become gummed up and contaminated after multiple successive contact landings, resulting in a progressively poorer electrical contact as the tuning run progresses. Conventional techniques for achieving good electrical contact over a long period of time rely on blindly applying a fixed and relatively large amount of overdrive force (e.g., overdriving Z position by 40 to 50 microns) to ensure good electrical contact between the electrical probes and the contact pads, but such blind overdriving will cause the electrical probes to degrade over time due to the persistent and repeated deflection of the probe tips.

Exemplary embodiments of the disclosure implement adaptive force sensing methods for contacting electrical probes with contact pads of devices for resistance measurements. In particular, probe contact methods are provided whereby contact overdriving (or probe overdriving) is performed in an adaptive manner in which the amount of contact overdrive (or prober overdrive) is performed in successive increments (e.g., 2-micron increments) to reach a minimal amount of contact overdrive which is sufficient to a achieve a good electrical contact before performing a resistance measurement.

It is to be noted that the terms “contact overdrive” or “probe overdrive” or “overdrive” are meant to be synonymous terms which generally denote an amount of additional Z displacement that is applied, starting from the initial “contact position” where the sample plane and probe plane are substantially co-located. During the contact overdrive, the electrical probes (e.g., probe tips) move in a Z direction into the surface of the contact (test) pads and thereby exert additional contact pressure on the contact (test) pad to scrub through any surface oxidation to assure a low resistance contact. In some embodiments, at the “initial contact position,” the sample plane and probe plane are substantially co-located, wherein overdrive is applied to by maintaining the probe plane in a fixed position while the Z position of the sample plane is moved (via the probe stage) by a given overdrive amount toward the probe plane to exert additional contact pressure between the electrical probes and the contact pads to enhance the electrical contact between the electrical probes and the contact pads of the device to be tested.

For example, in some embodiments, a probe contact process implements contact check operations, e.g., contact resistance checks and contact stability checks, to provide real-time feedback on probe contact quality prior to performing resistance measurements. Furthermore, in some embodiments, the contact resistance checks and contact stability checks are performed in conjunction with automated probe cleaning operations to clean probe tips of the electrical probes when necessary to remove contamination from the probe tips. As explained in further detail below, in some embodiments, the contact check operations and probe tip cleaning operations are implemented in conjunction with in situ resistance measurements that are performed as part of an automated iterative laser tuning process to progressively measure and tune the junction resistances of Josephson junctions (e.g., LASIQ process for tuning qubits in a qubit lattice), which can involve, e.g., thousands of automated probing operations.

It is to be noted that the exemplary probe contact check processes as discussed herein can be implemented in any electrical characterization system (e.g., prober system such as wafer-scale prober machine) which utilizes automated probing to perform electrical characterization tests on devices that are formed on a semiconductor wafer. In this regard, while exemplary embodiments of the disclosure are discussed in the context of performing probe contact checks in conjunction with performing resistance measurements, it is to be understood that the exemplary probe contact checks and probe cleaning operations can be performed in conjunction with other electrical characterization tests. In addition, while exemplary embodiments of the disclosure are discussed in the context of performing probe contact checks in conjunction with performing junction resistance measurements of Josephson junctions, it is to be understood that the exemplary probe contact checks and probe cleaning operations can be performed in conjunction with resistance measurement tests for other types of devices.

As noted above, in some embodiments, resistance measurements are performed using a 4-wire (Kelvin) resistance measurement process. For example, FIG. 5A schematically illustrates a process 500 for aligning contact probes to a Josephson junction of a quantum bit to perform a resistance measurement, according to an exemplary embodiment of the disclosure. In particular, FIG. 5A schematically illustrates an exemplary FOV 510, a plurality of electrical probes 520-1 and 520-2 (e.g., probe tips), and a superconducting qubit 530. The superconducting qubit 530 comprises a transmon qubit comprising a capacitor and Josephson junction connected in parallel. In particular, the superconducting qubit 530 comprises a first superconducting pad 531, a second superconducting pad 532, and a Josephson junction 533 coupled to, and disposed between, the first and second superconducting pads 531 and 532.

The first and second superconducting pads 531 and 532 comprise electrodes of a coplanar parallel-plate capacitor structure of the superconducting qubit 530. The Josephson junction 533 functions as a non-linear inductor which, when shunted with the capacitor formed by the first and second superconducting pads 531 and 532, forms an anharmonic LC oscillator with individually addressable energy levels (e.g., two lowest energy level corresponding to the ground state |0> and the first excited state |1>) with a given transition frequency f₀₁. As noted above, laser annealing process is applied to the Josephson junction 533 to monotonically increase the junction resistance the Josephson junction 533 to a target junction resistance, which results in an incremental decrease in the transition frequency f₀₁ of the superconducting qubit 530 to a target transition frequency.

The FOV 510 represents the area of the object that is imaged by the microscope unit 130, wherein the size of the FOV is generally determined by the magnification of the objective lens 137. In the exemplary camera-objective architecture of the microscope unit 130, the FOV of the objective lens is applied to an image sensor (e.g., focal plane array) of the camera 132. Since the image sensor is rectangular in shape, the images captured by the microscope unit 130 have a rectangular FOV, as shown in FIG. 5A, which does not capture the full circular FOV from the objective lens 137.

In some embodiments, the FOV of the objective lens comprises the entire qubit, which includes capacitor pads, Josephson junction and the various superconducting elements as shown in FIG. 5A. In other embodiments, the FOV may be larger, such that adjacent qubits are included in the image acquired by the microscope unit 130, which may allow for automated inspection and parallel probing by multiple sets of 4-wire (Kelvin) probes, as desired. In other embodiments, the FOV may be significantly smaller (using higher magnification of the objective lens 137) such that primary feature in the FOV is the Josephson junction 533, and image and pattern recognition may be performed using the junction feature. Higher magnification may yield more detail of the Josephson junction, and may be used to provide more accurate feedback when centering the junction and laser beam to the center of the FOV prior to the start of the anneal process.

FIG. 5A schematically illustrates an exemplary alignment process in which the plurality of electrical probes 520-1 and 520-2 (e.g., probe tips) are aligned in contact with the first and second superconducting pads 531 and 532 which comprise the electrodes of the coplanar parallel-plate capacitor of the superconducting qubit 530. In particular, FIG. 5A illustrates an electrical probe configuration to implement a 4-wire (Kelvin) resistance measurement, wherein the electrical probes 520-1 comprise two probes that make contact to the first superconducting pad 531, and wherein the electrical probes 520-2 comprise two probes that make contact to the second superconducting pad 532. In this embodiment, the first and second superconducting pads 531 and 532 serve as contact pads of the Josephson junction 533 on which the electrical probes are landed to perform an in situ junction resistance measurement.

In some embodiments, a template image that is used to perform a pattern recognition alignment process comprises an image of the entirety of the superconducting qubit 530 including first and second superconducting pads 531 and 532, and the Josephson junction 533. In other embodiments, a template image that is used to perform a pattern recognition alignment process comprises an image of the Josephson junction 533. In other embodiments, one or more additional features of the template image can be used to perform a pattern recognition alignment process.

FIG. 5B schematically illustrates a process 501 for aligning contact probes to a device under test to perform a resistance measurement, according to an exemplary embodiment of the disclosure. For ease of discussion FIG. 5B schematically illustrates the same exemplary FOV 510, and the same electrical probes 520-1 and 520-2 (e.g., probe tips) as shown and discussed above in conjunction with FIG. 5A. However, FIG. 5B schematically illustrate a device under test (DUT) 540 which is meant to generically represent any device or circuit element which is coupled to and between the first and second superconducting contact pads and 532, and which can be probed using the exemplary probing techniques as discussed herein.

In some embodiments, the qubit is in a “vertical” orientation, which corresponds to that shown in FIG. 5A, where the long edges of the capacitor pads are vertically arranged. In this case, the voltage (or current) may be sourced and current (or voltage) measured across the electrical probes 520-1 and 520-2. In other embodiments, the qubit is in a “horizontal” orientation, which corresponds to a 90-degree rotation of the image orientation in FIG. 5A, where the long edges of the capacitor pads are horizontally arranged. In such a case, the orientation of the voltage (or current) source and current (or voltage) measurement must be appropriately switched. Such a configuration may be simply achieved using a switch box, or electronic switch matrix that may be programmed in conjunction with a database of qubit positions and orientations, such that the electrical characterization measurement may be automatically configured for each qubits orientation and geometric requirements. In the case of FIG. 5B, where a generic DUT 540 is schematically illustrated, the appropriate measurement configuration may be appropriately selected and applied to a switch box, or electronic switch matrix programmed in conjunction with a database of DUT positions and orientations, such that the electrical characterization measurement may be automatically configured for each DUT geometry.

As noted above, in some embodiments, the optical apparatus and the electrical characterization apparatus are integrated such that a probing plane is displaced from an imaging plane by a specified “separation distance” such as 70 micron, or 80 microns, etc. When performing an electrical characterization test (e.g., a resistance measurement), after the target device to be probed is aligned to the FOV of the optical apparatus (e.g., the exemplary FOV 510, as shown in FIGS. 5A and 5B), the Z position of the X-Y-Z stage 142 is moved upwardly by a specified amount (e.g., the separation distance) to place the X-Y-Z stage 142 in the “contact position” where the sample plane and probing plane are substantially co-located, and where the initial contact is made between the electrical probes and the contact pads (or test pads) that are coupled to the given Josephson junction or DUT.

In the initial “contact position,” it is assumed that a minimal amount of contact force is applied between the contact (test) pads and the probe tips of the electrical probes, which is sufficient to potentially achieve good electrical contact for the electrical characterization test. As noted above, however, when the initial “contact position” does not result in a good electrical contact for the probing test, a contact overdrive process (or probe overdrive process) can be performed in a progressive manner, wherein, e.g., the Z position of the X-Y-Z stage 142 is successively increased in small increments (e.g., 2 micron increments) to reach a minimal amount of contact overdrive which is determined (via contact resistance and contact stability checks) to be sufficient to achieve a good electrical contact before performing the electrical characterization test (e.g., resistance measurement). In some embodiments, the incremental contact overdrive process is limited by a “maximum contact overdrive” which denotes a maximum amount of Z displacement from the initial Z “contact position.” The “maximum contact overdrive” provides a constraint on the amount of contact overdrive that can be utilized to make contact between the electrical probes and the contact pads of the DUT to prevent, or otherwise minimize the likelihood or damage to the electrical probes and the contact pads as a result of applying excessive force to make electrical contact between the probes and the contact pads.

In some embodiments, prior to performing laser annealing and probing operations using a laser annealing system, an initialization process is performed to configure the laser annealing system to have a properly defined contact position, anneal position, safety position, and separation distance, to ensure that no damage occurs to the electrical probes or sample (e.g., quantum chip) when performing probing or laser annealing operations. In particular, the initialization process is preferably performed during an initial setup phase of a laser annealing system, or when the laser annealing system is not operated for some period of time where it is assumed that various mechanical components have drifted from their initially defined positions (e.g., through thermal drift). In such instances, it is preferable to initialize the laser annealing system using a suitable initialization protocol, an exemplary embodiment of which is illustrated in FIG. 5C.

In particular, FIG. 5C illustrates a flow diagram of a method for initializing a laser annealing system, according to an exemplary embodiment of the disclosure. FIG. 5C illustrates an exemplary initialization process 550 to ensure that the positions of the probing plane, the imaging plane, the annealing plane, and the sample surface are well defined, to allow safe probing and laser tuning operations. For illustrative purposes, the exemplary initialization process 550 will be discussed in the context of the exemplary laser annealing system 100 of FIG. 1. The initialization process 550 may be performed on either (i) a quantum chip having a set of dedicated test pads that can be used to perform the initialization process or (ii) a dedicated initialization test chip with test pads.

The initialization process 550 begins by obtaining specified parameters for initializing the laser annealing system (block 551). For example, in some embodiments, the specified parameters include (i) a specified separation distance, and (ii) a specified safety position. In some embodiments, the parameters are defined and provided by an operator of the laser annealing system 100, or otherwise obtained through default configurations stored in the prober control unit 113. As noted above, the separation distance specifies a displacement in the Z position between the X-Y-Z stage 142 where (i) the stage is in the contact position, where the probes are in contact with the sample surface, and (ii) the sample is at the anneal position, which will also be substantially co-located with the image plane. The safety position specifies the position of the X-Y-Z stage 142 such that no feature on the sample surface will have a Z position which intersects with the probing plane, or equivalently, no feature on the sample will collide with the probe tips while in the safety position.

The initialization process proceeds by moving the X-Y-Z stage 142 to an initialization location (block 552) such that the electrical probes 144 are properly disposed above, and aligned to, test contact pads on a quantum chip, where the contact resistance may be safely measured without risk of damage to any actual devices (e.g., qubits) on the quantum chip. As noted above, in some embodiments, the initialization position can be the location of test contact pads on a dedicated test chip which comprises an array of conducting contact pads that are available for use to safely contact the electrical probes 144 to perform the initialization process. Once the electrical probes 144 are properly positioned with the test contact pads, the Z position of the X-Y-Z stage 142 is incremented by a specified fixed amount (e.g., 2-micron increments) towards the electrical probes 144 (block 553), and the contact resistance is measured (block 554).

At each increment, a determination is made as to whether the measured contact resistance is below a specified contact resistance threshold (bock 555). In some embodiments, the specified contact resistance threshold is set to 100 ohms or less, or any other desired threshold value. If it is determined that the contact resistance is not below the contact resistance threshold (negative determination in block 555), a determination is made as to whether the process is at a maximum Z position increment (block 556). In some embodiments, the maximum Z position increment is set at 140 microns (or twice the specified separation distance), or any other value that would be considered safe for the laser annealing system 100. If it is determined that the process is not at the specified maximum Z position increment (negative determination in block 556), the process proceeds to increment the X-Y-Z stage 142 towards the electrical probes 144 by the specified fixed amount, e.g., 2 microns (return to block 553) and the process loop of blocks 554, 555, and 556 is repeated.

If, after numerous Z position increments, it is determined that the process is at the maximum Z position increment (affirmative determination in block 556), the process proceeds to reconfigure the initialization position of the X-Y-Z stage 142 to allow the laser annealing system 100 to be safely initialized (block 557), and the process (blocks 553, 554, 555, and 556) is repeated until it is determined that the measured contact resistance is below the contact resistance threshold (affirmative determination in block 555). When the measured contact resistance is below the contact resistance threshold, this is deemed to indicate a successful contact between the sample and the probing plane, or equivalently, the sample plane and probing plane are co-located, and the X-Y-Z stage 142 is in the “contact position.”

Next, the X-Y-Z stage 142 is lowered in the Z position by the specified “separation distance” (e.g., 70 microns) such that the X-Y-Z stage 142 is deemed to be placed in the “anneal position” (block 558). At this point, the image focal plane may not yet be substantially co-located with the sample plane, i.e., the sample may be out of focus. In this case, the Z position of the microscope unit 130 is adjusted to adjust the focal plane to focus on the sample (block 559). In some embodiments, the Z position of the microscope unit 130 is manually adjusted using Z position adjustment to adjust the focal plane. In some embodiments, the Z position of the microscope unit 130 is or automatically adjusted, in the case where the microscope is mounted on its own automated X-Y-Z stage, and controlled by the imaging control unit 112. The focusing step of block 559 ensures that the imaging focal plane is substantially co-located with the sample plane.

Upon completion of the focusing operation (block 559), the image plane and laser annealing plane are substantially co-located, whereby both imaging and annealing can now occur at the “anneal position.” Finally, the information regarding the “contact position,” the “anneal position,” the “separation distance,” and the “safety position” are stored (block 560) for use in subsequent probing and anneal processes. In this manner, the laser annealing system 100 can be prepared through the annealing initialization sequence to probe and tune Josephson junctions without risking probe or sample damage. For example, whenever a sample is in focus under the microscope unit 130, the X-Y-Z stage 142 will be deemed to be at the anneal position. If probing is desired, the Z position of the X-Y-Z stage 142 is increased (stage is moved up) by an amount specified by the separation distance, such that the contact position is achieved and probing may safely commence. In some embodiments, a slight initial overdrive may be applied in conjunction with the contact position to ensure good electrical contact between the probe tips and the sample contact pads.

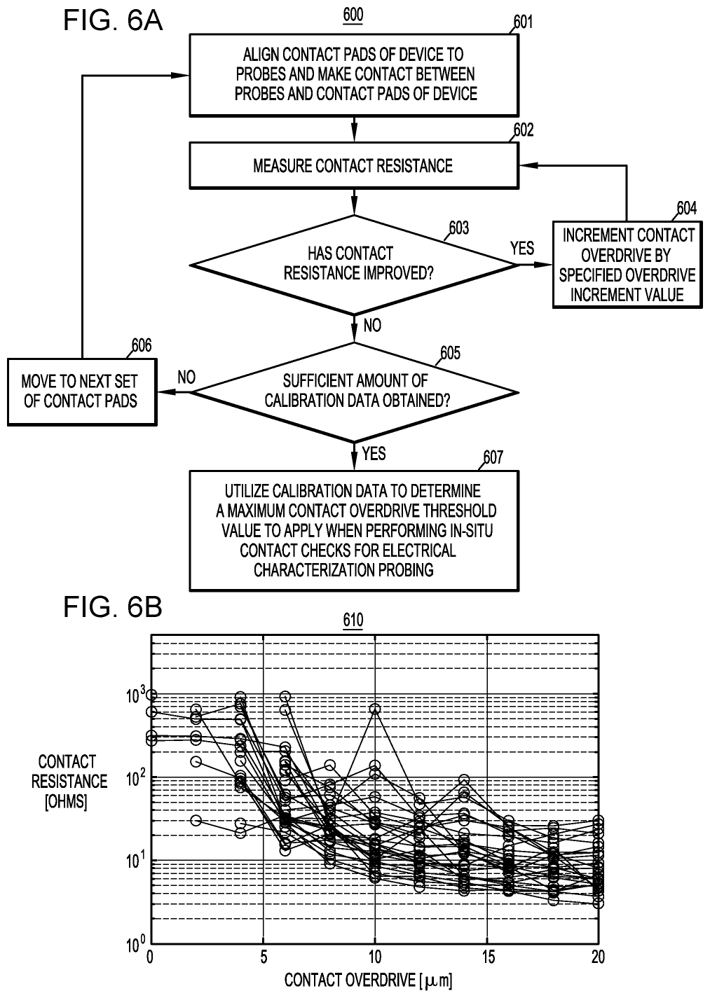

FIGS. 6A and 6B illustrate a calibration process to determine a maximum contact overdrive for contacting electrical probes and test pads, according to an exemplary embodiment of the disclosure. In particular, FIG. 6A illustrates a flow diagram of a calibration process 600 for generating and utilizing contact calibration data to determine a maximum contact overdrive threshold value, according to an exemplar embodiment of the disclosure, and FIG. 6B graphically illustrates contact calibration data 610 that is generated and utilized by the calibration process of FIG. 6A to determine a maximum contact overdrive threshold value, according to an exemplary embodiment of the disclosure. In an exemplary embodiment, the calibration process generates calibration data and utilizes the calibration data to define a maximum contact overdrive threshold value (denoted ODₘₐₓ) which corresponds to a maximum displacement from the initial default “contact position” to some contact overdrive position after which no further improvement (i.e., reduction) in contact resistance is achieved by applying more contact overdrive.

Referring to FIG. 6A, a quantum chip is placed on the X-Y-Z stage 142 of the prober unit 140, and the control system 110 commences the automated calibration process 600. The calibration process selects a set of contact pads of a given device (e.g., Josephson junction of a qubit) on the quantum chip, aligns the selected contact pads to the electrical probes, and moves the X-Y-Z stage 142 (in the Z direction) to place the X-Y-Z stage 142 in the “contact position” where the sample plane and probing plane are substantially co-located, and where the initial contact is made between the electrical probes and the contact pads (or test pads) (block 601). In some embodiments, the calibration process may be performed on a set of contact pads of a given device (e.g., Josephson junction of a qubit) on the quantum chip. In other embodiments, the calibration process may be performed on a set of test contact pads with the specific purpose of contact testing and calibration. These may be, for example, gold pads, or metal pads comprised of similar or identical superconducting material as the capacitor pads in the Josephson junction (e.g., niobium).

The calibration process then proceeds to measure the contact resistance (denoted R_{CONT}) between the electrical probes and the given contact pads (block 602) and determine whether the contact resistance has improved (e.g., decreased) relative to a previous measured contact resistance for the given contact pads (block 603). For the initial contact resistance measurement of a given set of contact pads, since there is no previous contact resistance measurement to compare with, the calibration process will automatically determine that the contact resistance has improved (affirmative determination in block 603), and then proceed to increment the amount of contact overdrive by a specified overdrive increment value (block 604). In some embodiments, the overdrive increment value (denoted OD_{inc}) is set at 2.0 μm, or 3.0 μm, or any other desired amount. In some embodiments, the value OD_{inc} specifies an amount of incremental increase to apply in the Z-direction of the X-Y-Z stage 142 to achieve an incremental amount of contact overdrive and thereby apply additional contact force between the electrical probes and the contact pads.

The calibration process then proceeds to remeasure the contact resistance between the electrical probes and the given contact pads (return to block 602) and determine whether the contact resistance has improved (e.g., decreased) relative to the previous measured contact resistance for the given contact pads (block 603). The calibration process loop (blocks 602, 603, and 604) continues until it is determined that a currently measured contact resistance does not result in any further improvement (e.g., no further decrease) in the contact resistance (negative determination in block 603).

The calibration proceeds to obtain a sufficient amount of calibration data to determine a maximum contact overdrive threshold value ODₘₐₓ. For example, if the given quantum chip comprises 50 Josephson junctions of 50 qubits, the calibration data can be obtained by performing the contact resistance measurements on the contacts pads for each of, e.g., 10 or 20 Josephson junctions, etc. If a sufficient amount of calibration data has not been generated (negative determination in block 605), the calibration process moves to a next set of contact pads of a next device (block 606), and the contact resistance measurement process (blocks 601, 602, 603, and 604) is repeated. Once a sufficient amount of calibration data is generated (affirmative determination in block 605), the calibration process utilizes the calibration data to determine a maximum contact overdrive threshold value ODₘₐₓ to be subsequently utilized when performing in situ contact checks for electrical characterization probing (block 607), such as described in further detail below.

FIG. 6B graphically illustrates an exemplary set of contact calibration data 610 that is generated by the calibration process 600 of FIG. 6A, wherein the calibration data comprises a plurality of curves which represent measured contact resistance in Ohms (Y-axis) of a function of contact overdrive (X-axis). Each curve comprises a series of contact resistance measurements associated with the contact pads of a respective one of the devices among a plurality of devices whose contact pads were tested in the calibration process. Each curve comprises a respective series of measurements which show that progressively incrementing the contact overdrive (e.g., OD_{inc} increments of 2 microns) improves the probe contact resistance. In some embodiments, as noted above, the calibration data is utilized to define a maximum contact overdrive threshold value ODₘₐₓ.

For example, in some embodiments, a value for ODₘₐₓ is determined by computing an average of the maximum increment overdrive values determined from the calibration curves. For example, the exemplary calibration curves in FIG. 6B show that the maximum contact overdrive values for the curves fall within a range of about 15 microns to about 20 microns (e.g., flat regions of the curves in the range of about 15 microns to about 20 microns). In this regard, based on the contact calibration data 610 shown in FIG. 6B, a maximum contact overdrive threshold value ODₘₐₓ may be determined as some value within the range of about 15 microns to about 20 microns. It is to be noted that the given the determined maximum contact overdrive threshold value ODₘₐₓ and the threshold increment value OD_{inc} applied in the calibration process of FIG. 6A, an integer number N of contact overdrive increments (maximum number of increments, Nₘₐₓ) can be determined as Nₘₐₓ ODₘₐₓ/OD_{inc} For example, assuming that maximum contact overdrive threshold value is determined as ODₘₐₓ=20.0 μm, and that the threshold increment value is set to OD_{inc}=2.0 μm, then maximum number of increments Nₘₐₓ ODₘₐₓ/OD_{inc} can be determined as Nₘₐₓ 20.0 μm/2.0 μm=10.

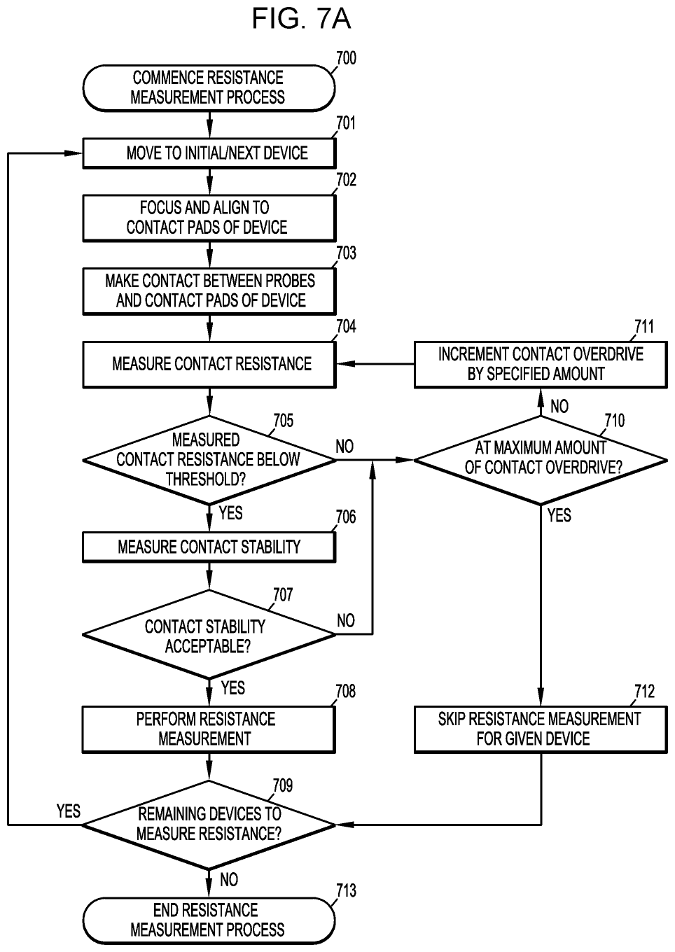

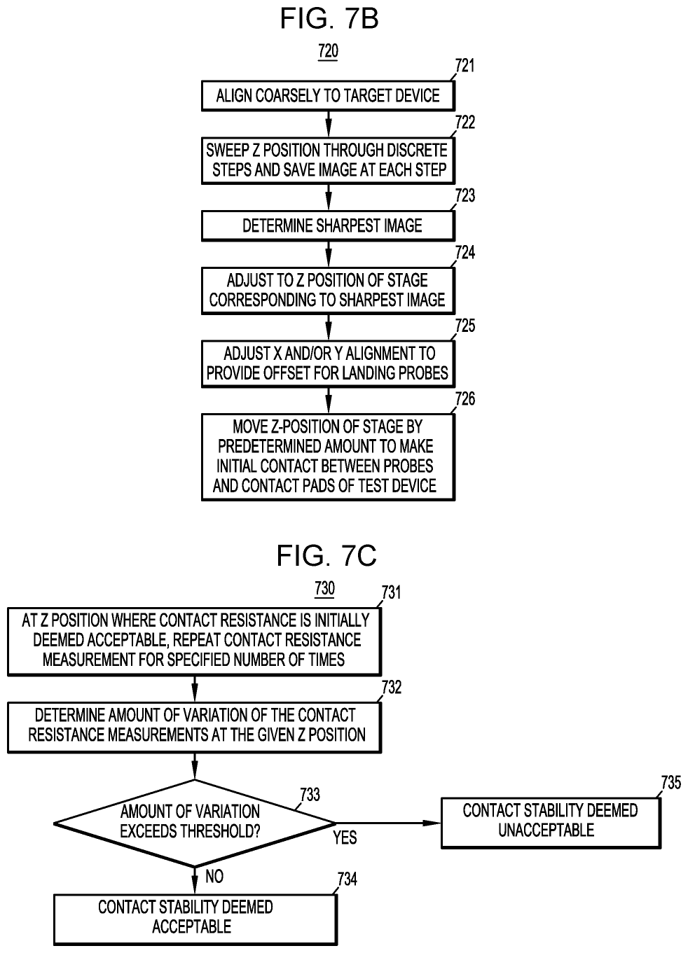

FIG. 7A illustrates a flow diagram of a method for performing probe contact checks in conjunction with performing electrical characterization measurements of a plurality of devices, according to an exemplary embodiment of the disclosure. In particular, FIG. 7A illustrates a sequential process for performing probe contact checks in conjunction with performing resistance measurements of a plurality of devices on a given chip. For example, in an exemplary embodiment, FIG. 7A illustrates a resistance measurement process that can be utilized to measure junction resistances of Josephson junctions of qubits in a given lattice of a quantum chip, wherein in situ contact check operations, e.g., contact resistance checks and contact stability checks, to provide real-time feedback on probe contact quality prior to performing resistance measurements. FIG. 7A comprises an exemplary embodiment for electrical characterization probing which implements an adaptive force sensing process for overdriving probe contacts, such that a minimal amount of contact overdrive is implemented to achieve good electrical contact before performing a resistance measurement. FIG. 7A illustrates a round-robin resistance measurement process in which the target devices on a given chip (e.g., Josephson junctions of all qubits on a multi-qubit device) are successively probed to perform a resistance measurement.

Referring to FIG. 7A, a quantum chip is placed on the X-Y-Z stage 142 of the prober unit 140, and the control system 110 commences an automated resistance measurement process (block 700). The automated resistance measurement process selects an initial target device, e.g., Josephson junction of a qubit) on the quantum chip for electrical probing and testing, and moves the X-Y-Z stage 142 to place the selected device in the FOV of the optical system (block 701). The automated resistance measurement process selects an initial device (e.g., Josephson junction of a qubit) and moves to the selected device (block 701) by causing the X-Y-Z stage 142 to laterally move (in X and Y directions) to place the selected device into the FOV of the microscope unit 130. The resistance measurement process initiates control operations to cause the microscope unit and the probe unit to perform a focus and alignment process to ensure a proper focus to the focal plane and proper alignment of the target device within the FOV of the microscope unit 130 for the purpose of performing a resistance measurement (block 702) and ensuring safe landing zones for the probes. An exemplary focusing process will be described below in conjunction with FIG. 7B. The focus ensures that the sample plane (e.g., the plane which contains the target device to be probed) is at the focal plane (i.e., plane of focus) of the objective lens 137. The focus can be adjusted by adjusting the Z position of the X-Y-Z stage 142. As noted above in conjunction with FIGS. 5A and 5B, the alignment to the target device (e.g., Josephson junction) may be performed using a pattern recognition operation to determine an amount of offset (if any) between the sample image taken of the Josephson junction in the FOV and a template image of the Josephson junction aligned to the center of the FOV (block 702). In some embodiments, the pattern recognition operation may be performed using a cross-correlation between the sample image and the template image to quantify the quality of the match, and the corresponding amount of offset (if any) required to optimize the match. In other embodiments, the pattern recognition operation may be performed using a machine learning process to align the target device to the center of the FOV. In addition, depending on the given iteration, the alignment can be slightly adjusted in the X and/or Y position to ensure that the electrical probes of the prober unit land on a different location of the contact pads of the device to avoid repeated probe contact to the same location on the contact pads over multiple iterations of electrical probing. Such repeated probe contacts may be detrimental to contact quality as a result of gouging of the contacts deeper into the same contact sites over repeat measurement iterations, as the probing overdrive is successively increased.

Next, the automated process causes the prober unit to make contact between the electrical probes and the contact pads of the target device (block 703). For example, in some embodiments, the automated resistance measurement process causes the X-Y-Z stage 142 to be moved in the Z direction to place the X-Y-Z stage 142 in the initial (default) “contact position” where the sample plane and probing plane are substantially co-located, and where the initial contact is made between the electrical probes and the contact pads of the target device to be measured. As noted above, in the initial default “contact position,” a minimal amount of contact force is applied between the contact pads (of the target device) and the probe tips of the electrical probes, which may be sufficient to achieve good electrical contact for the electrical characterization test. However, contact resistance and contact stability checks are performed to ensure that a good electrical contact is achieved before performing a resistance measurement.

In particular, the automated resistance measurement process initiates a contact resistance check operation by measuring the contact resistance R_{CONT} between the electrical probes and the contact pads (block 704). For example, for a 4-wire resistance measurement as schematically shown in FIGS. 5A and 5B, the contact resistance check operation measures the contact resistance R_{CONT} between the first pair of electrical probes 520-1 and the first contact pad 531, and between the second pair of electrical probes 520-2 and the second contact pad 532. Any suitable method can be used to measure the contact resistance. For example, in an exemplary embodiment, the contact resistance between the first contact pad 531 and the first pair of electrical probes 520-1 can be measured by applying a voltage across the pair of electrical probes 520-1 and measuring the resulting current. Similarly, the contact resistance between the second contact pad 532 and the second pair of electrical probes 520-2 can be measured by applying a voltage across the second pair of electrical probes 520-2 and measuring the resulting current.

The automated process compares the measured contact resistance with a contact resistance threshold, to determine whether to perform an electrical characterization measurement of the target device, based on a result of comparing the measured contact resistance with the contact resistance threshold. For example, in an exemplary embodiment, the automated process compares the measured contact resistance R_{CONT} with a specified contact resistance threshold R_{CONT_thresh} to determine whether the measured contact resistance R_{CONT} for each individual pair of contact probes is below the specified contact resistance threshold R_{CONT_thresh}, e.g., R_{CONT}<R_{CONT_thresh} (block 705). For example, in some embodiments, the threshold value RCON thresh IS set to 100 Ohms or less, as desired.

If it is determined that the measured contact resistance R_{CONT_i} s below the contact resistance threshold R_{CONT_thresh} (affirmative determination in block 705), the automated process proceeds to perform a contact stability check operation by measuring the contact stability (block 706) to determine whether an acceptable contact stability is achieved (block 707). In an exemplary embodiment, the contact stability check operation is performed by a process which comprises remeasuring the contact resistance a specified number of times (e.g., 3 or more times), determining a degree of variation of the remeasured contact resistances, and determining whether or not an acceptable contact stability is achieved based on the determined degree of variation of the remeasured contact resistances. An exemplary contact stability check operation will be discussed in further detail below in conjunction with FIG. 7C. If it is determined that the contact stability is acceptable (affirmative determination in block 707), the automated process proceeds to perform a resistance measurement to measure the resistance of the target device (block 708). In some embodiments, the resistance measurement is performed using a 4-wire (Kelvin) resistance measurement operation as discussed above.

On the other hand, after measuring the contact resistance of the target device (block 704), if it is determined that the measured contact resistance R_{CONT_i} s not below the contact resistance threshold R_{CONT_thresh} (negative determination in block 705), the automated process determines, for the given iteration, whether the maximum amount of contact overdrive ODₘₐₓ has been reached (block 710). As noted above, the value of ODₘₐₓ is determined from calibration data (FIGS. 6A and 6B) and represents a maximum displacement from the initial default “contact position” after which no further improvement (i.e., reduction) in contact resistance is achieved by applying and additional contact overdrive increment OD_{inc}.

If it is determined that the maximum amount of contact overdrive ODₘₐₓ has not been reached (negative determination in block 710), the automated process proceeds to increment the contact overdrive by a specified amount OD_{inc} (block 711), and then remeasure the contact resistance (block 704) to determine whether or not the measured contact resistance R_{CONT_i} s below the contact resistance threshold R_{CONT_thresh} (block 705). The process loop (blocks 704, 705, 710, and 711) is repeated until either (i) the threshold condition in block 705 is satisfied and the process proceeds with the contact stability check operation, or until (ii) the previous increment OD_{inc} (block 711) resulted in reaching the maximum amount of contact overdrive ODₘₐₓ (affirmative determination block 710) in which case the resistance measurement is skipped for the given device (block 712) to avoid potential damage to the electrical probes and/or the contact pads of the target device being measured. As noted above, in some embodiments, OD_{inc}=2.0 μm. Assuming that ODₘₐₓ=20.0 μm, the decision in block 710 can be made by tracking a number of increments N_{inc} and determining whether N_{inc}<Nₘₐₓ, where Nₘₐₓ=ODₘₐₓ/OD_{inc}. In an exemplary embodiment, Nₘₐₓ 20.0 μm/2.0 μm==10.

Furthermore, after measuring the contact stability between the electrical probes and the contact pads of the target device (block 706), if it is determined that the contact stability is not acceptable (negative determination in block 707), the process flow proceeds to determine, for the given iteration, whether the maximum amount of contact overdrive ODₘₐₓ has been reached (block 710), and the process flow of blocks 704, 705, 706, 707, 710, and 711 is repeated until either (i) the threshold condition in block 707 is satisfied and the process proceeds to perform the resistance measurement for the target device (block 708), or until (ii) the previous overdrive increment OD_{inc} (block 711) resulted in reaching the maximum amount of contact overdrive ODₘₐₓ (affirmative determination block 710) in which case the resistance measurement is skipped for the given device (block 712) to avoid potential damage to the electrical probes and/or the contact pads of the target device being measured.

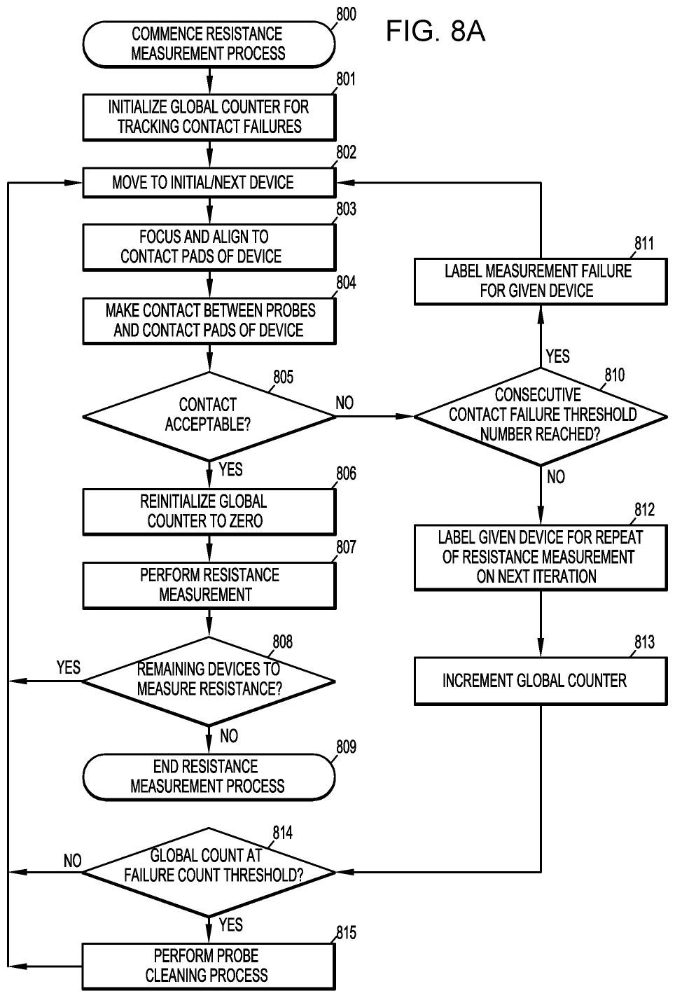

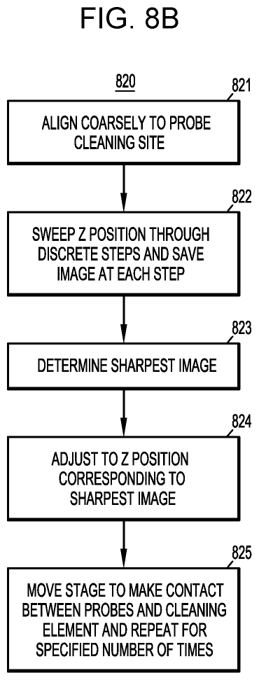

After performing the resistance measurement for the target device (block 708) or skipping the resistance measurement for the target device (block 712), the automated process determines if there are one or more remaining devices (e.g., Josephson junctions) that need to be probed for a resistance measurement (block 709). The automated process will determine that there are one or more remaining devices (e.g., Josephson junctions) that need to be probed for a resistance measurement (affirmative determination in block 709) if there still exists one or more target devices for which a resistance measurement has not yet been performed and/or one or target devices for which a resistance measurement was skipped (in block 712) in which case a resistance measurement operation for a skipped device will be redone, at least for a specified maximum number of times before a measurement fail condition reached, as will be explained in further detail below in conjunction with FIG. 8A. When there are no remaining devices to be measured (negative determination in block 709), the automated resistance measurement process is terminated (block 713).

FIG. 7B illustrates a flow diagram of a method for focusing and aligning to a target device for performing an in situ resistance measurement, according to an exemplary embodiment of the disclosure. In some embodiments, FIG. 7B illustrates an exemplary process 720 for implementing the focus/alignment and probe contact processes in blocks 702 and 703 of FIG. 7A. An initial step of the process 720 involves performing a coarse alignment in which the X-Y-Z stage 142 is controllably operated to move the target device (e.g., Josephson junction) in alignment to a center of the FOV of the microscope unit (block 721). The prober unit 140 is then controlled to sweep the Z position of the X-Y-Z stage 142 through a series of discrete steps (positions), and the camera 132 of the microscope unit 130 is controlled to capture and save a digital image of the sample (sample image) in the FOV at each Z position (block 722).

The process then determines a sharpest sample image among the plurality of sample images taken at the different Z positions (block 723). In some embodiments, the sharpest sample image is determined using, e.g., an edge detection process to identify the sample image with the sharpest edges (e.g., sharpest edges of contact pads to which the electrical probes will make contact). The X-Y-Z stage 142 is then controlled to move to the target Z position corresponding to the sharpest sample image (block 724), wherein it is assumed that at the target Z position, the sample imaging plane with the contact pads is displaced from the probing plane at the known “separation distance” (e.g., 70 microns).

Next, an optional step of slightly adjusting the X and/or Y position of the target contact pads of the target device can be performed to provide some small offset from the original center alignment (block 725), which allows the probe tips of the electrical probes to make contact to the contact pads of the target device (e.g., Josephson junction) in desired target contact positions which are different from the contact positions made to the contact pads for previous in situ junction resistance measurements of previous iterations.

Finally, the automated process causes the prober unit to move in the Z direction by an amount that corresponds to the specified “separation distance” to make the initial contact between the electrical probes and the contact pads of the target device (block 726). The increase of the Z position of the X-Y-Z stage 142 by an amount equal to the specified “separation distance” causes the X-Y-Z stage 142 to be positioned in the initial default “contact position” where the sample plane and probing plane are substantially co-located, and where the initial contact is made between the electrical probes and the contact pads of the target device to be measured. Subsequent to moving the X-Y-Z stage 142 to the “contact position,” the Z position may be incremented in accordance with the process described in FIG. 7A to ensure that the contact resistance is below a specified contact resistance threshold (e.g., 100 ohms or less). Once the specified threshold is reached, contact stability may be checked to ensure there is no intermittent contact which may damage the, e.g., Josephson junction or DUT.

FIG. 7C illustrates a flow diagram of a method for performing a contact stability check operation, according to an exemplary embodiment of the disclosure. In some embodiments, FIG. 7C illustrates an exemplary contact stability check process 730 for implementing the contact stability operation in blocks 706 and 707 of FIG. 7A. As an initial step, at a given Z position (or given contact overdrive position) where the contact resistance condition is satisfied, the contact stability check process remeasures the contact resistance a specified number of times (block 731). For example, in some embodiments, the contact resistance is measured 3 or more times. The contact stability check process analyzes the remeasured contact resistance values to determine an amount of variation of the contact resistance values (block 732). For example, in some embodiments, the amount of variation is determined by computing a standard deviation of the set of contact resistance values R_{CONT_i} (for i=1, . . . , n), where n is equal to the number of times the contact resistance is remeasured for the contact stability check operation. The standard deviation for the contact resistance (denoted σ_{cont} for the set of contact resistance values R_{CONT_i} can be determined as follows:

$${σ}_{cont} = \sqrt{\frac{1}{n} {\sum }_{i}^{n} {( {R}_{CONT \_ i} - μ )}^{2}}$$

where μ denotes a mean (or average) of all the contact resistance values R_{CONT_i} obtained from repeating the contact resistance measurement n times at the given contact overdrive position.

Next, the contact stability check operation determines whether or not the amount of variation exceeds a specified variation threshold (block 733). For example, in some embodiments, the contact stability check process compares the computed value σ_{cont} to a specified threshold value σₜₕ to determine, e.g., whether σ_{cont}<σₜₕ. If the amount of variation is determined to not exceed the specified variation threshold (negative determination in block 733), the contact stability is deemed acceptable (block 734). On the other hand, if the amount of variation is determined to exceed the specified variation threshold (affirmative determination in block 733), the contact stability is deemed unacceptable (block 735).

FIG. 8A illustrates a flow diagram of a method for performing probe contact checks in conjunction with performing electrical characterization measurements of a plurality of devices, according to another exemplary embodiment of the disclosure. In particular, similar to the process of FIG. 7A as described above, the process of FIG. 8A performs probe contact checks in conjunction with performing electrical characterization measurements of a plurality of devices. However, the process flow of FIG. 8A implements a process to keep track of a number of contact check failures for a given target device, which results in skipping the resistance measurement for the given target device (e.g., block 712, FIG. 7A), and labeling a resistance measurement failure for the target device when the resistance measurement for the target device is skipped for a specified number of times (e.g., 3 times). In addition, the process flow of FIG. 8A implements a process to keep track of a global number of successive contact check failures, and initiate an automated probe cleaning process when the global number of successive contact check failures has reached a threshold number (e.g., 5 successive contact check failures).

Referring to FIG. 8A, a quantum chip is placed on the X-Y-Z stage 142 of the prober unit 140, and the control system 110 commences an automated resistance measurement process (block 800). As an initial step, the automated process initializes (e.g., set to 0) a global failure counter (denoted NumFail) for tracking a number of successive contact failures which occur during the automated resistance measurement process (block 801). The automated resistance measurement process selects an initial target device, e.g., Josephson junction of a qubit) on the quantum chip for electrical probing and testing, and moves the X-Y-Z stage 142 to place the selected device in the FOV of the optical system (block 802) and performs a focus and alignment process to ensure a proper focus to the focal plane and proper alignment of the target device within the FOV of the microscope unit 130 for the purpose of performing a resistance measurement (block 803). The placement, focus, and alignment operations (in blocks 802 and 803) are performed in the same or similar manner to the placement, focus, and alignment operations (in blocks 701 and 702) of the process of FIG. 7A, the details of which need not be repeated.

Next, the automated process causes the prober unit to make contact between the electrical probes and the contact pads of the target device (block 804). For example, in some embodiments, the automated resistance measurement process causes the X-Y-Z stage 142 to be moved in the Z direction to place the X-Y-Z stage 142 in the initial (default) “contact position” where the sample plane and probing plane are substantially co-located, and where the initial contact is made between the electrical probes and the contact pads of the target device to be measured. Thereafter, contact resistance and contact stability checks are performed to ensure that a good electrical contact is achieved before performing a resistance measurement using the same or similar contact resistance and contact stability check operations discussed above in conjunction with, e.g., FIGS. 7A and 7B.

In particular, the process performs contact resistance and contact stability check operations to determine whether the electrical contact is acceptable (block 805). The electrical contact is deemed acceptable (affirmative determination in block 805) when the conditions for acceptable contact resistance and contact stability are satisfied (e.g., affirmative determination in in blocks 705 and 707, FIG. 7A). The automated process then proceeds to reinitialize the global fail counter (NumFail) to zero (0) (block 806) and perform a resistance measurement operation to measure the resistance of the target device (block 807).

On the other hand, if the electrical contact is deemed unacceptable for the (negative determination in block 805), the process proceeds to determine whether a number of consecutive contact failures for the target device has reached a contact failure threshold number (block 810). The electrical contact for the target device is deemed unacceptable when either one of the conditions for acceptable contact resistance and contact stability are not satisfied (e.g., negative determination in blocks 705 or 707, FIG. 7A), resulting in the resistance measurement being skipped (block 712) for the target device due to the inability to obtain an acceptable electrical contact for the resistance measurement. If it is determined that the number of consecutive contact failures for the target device has reached a contact failure threshold number (affirmative determination in block 810), the target device is labeled to have a resistance measurement failure (block 811). For example, in some embodiments, the contact failure threshold number is set to 3. In this instance, if there are three (3) consecutive contact failures when attempting to measure the resistance of the target device, the target device will be labeled with a resistance measurement failure to provide an indication that the resistance of the target device cannot be measured for some reason (e.g., defective contact pads, or some other physical defect that prevents the ability to achieve a stable, low contact resistance electrical contact between the electrical probes and the contact pads of the target device). Subsequent to labeling the target device with a resistance measurement failure, the probing process in FIG. 8A proceeds to the next device in the measurement process, and the process continues for the remaining devices on the sample to be measured. If there are no remaining devices to be measured, the resistance measurement process terminates.

On the other hand, if it is determined that the number of consecutive contact failures for the target device has not reached a contact failure threshold number (negative determination in block 810), the target device is labeled for a repeat resistance measurement on a next round-robin iteration in which the process flow of FIG. 8A is repeated and performed on each target device that is labeled (in the current round-robin iteration) for a repeat resistance measurement (block 812). The global failure counter NumFail is then incremented by 1 (block 813) to count the current contact failure for the target device as determined in block 805.

Next, the automated process determines whether the global failure counter has reached a failure count threshold, denoted N_{fail_thresh} (block 814). In some embodiments, the failure count threshold is set to N_{fail_thresh}=5, or any desired number. The global failure counter NumFail tracks number of successive contact check failures which result in skipping the resistance measurement for N_{fail_thresh} successive times in a row for different target devices. While the contact failure threshold specified in block 810 tracks a number of times a resistance measurement has been successively skipped (block 712, FIG. 7A) for a given target device in different successive round-robin iterations of the process of FIG. 8A, the global failure counter NumFail tracks number of successive contact check failures which result in skipping the resistance measurement for N_{fail_thresh} successive times in a row for different target devices in the same round-robin iteration of the process of FIG. 8A. Typically, contact failures that occur on different target devices would be indicative of an issue with the probes itself (e.g., probe tip contamination), as opposed to the less likely possibility that consecutive devices are defective for probing.

When the global failure counter has reached a failure count threshold N_{fail_thresh} (affirmative determination in block 814), an automated probe cleaning process is performed (block 815). An exemplary probe cleaning process will be described below in conjunction with FIG. 8B. When the global failure counter reaches the failure count threshold N_{fail_thresh}, this provides an indication that the probe tips of the electrical probes may be dirty or contaminated, thereby preventing the ability to achieve acceptable electrical contacts with the contact pads of the target devices that are to be probed for resistance measurements. Once the automated probe cleaning process is completed, the automated resistance measurement process proceeds to select a next target device to probe for performing a resistance measurement (return to block 802), the process repeats.

After performing a resistance measurement for a target device (block 807), the automated process determines if there are one or more remaining devices (e.g., Josephson junctions) that need to be probed for a resistance measurement (block 808). For example, the automated process will determine whether there are one or more remaining devices (e.g., Josephson junctions) that have not been probed (either successfully or unsuccessfully) in the given round-robin iteration, and still need to be probed for a resistance measurement, and then proceed to select a next target device (return to block 802) and repeat the process if it is determined that there is one or more remaining devices that need to be probed in the given iteration (affirmative determination in block 808). On the other hand, if all devices have been probed in the given round-robin iteration, the process determines (in block 808) whether there exists one or more devices for which the resistance measurement was skipped (in the given round-robin iteration) and the device was not labeled with a measurement failure (i.e., the number of consecutive contact failures for the target device has not reached the contact failure threshold number (e.g., 3), block 810). In this regard, if there are any remaining devices that need to be “re-probed” (and which are not labeled with a measurement failure), the process proceeds to perform another round-robin iteration of the process shown in FIG. 8A to attempt to measure the resistance of the target devices that need to be re-probed. In this instance, the next round-robin process only iterates over the target devices whose resistance measurement were skipped in the current iteration.

When there are no remaining devices to probe to perform resistance measurements (negative determination in block 808), the automated resistance measurement process is terminated (block 809) at the completion of the automated resistance measurement process, whereupon each target device will have either a corresponding measured resistance value, or a label which indicates a measurement failure for the given device.

In other embodiments, the automated probe cleaning process (block 815) can be performed at predefined time intervals (as determined/tracked by a probe cleaning timer/counter) during a long and extensive tuning process in which a large number of in situ probing operations are performed. This may occur, for example, when performing an iterative laser tuning process (e.g., FIG. 9A) where a large number of in situ probing operations are performed to measure the junction resistance of Josephson junctions that are adaptively and progressively tuned using multiple laser annealing operations, with junction resistance measurements being performed between laser annealing operations to track the progression in resistance shifting of the Josephson junctions to respective target junction resistances. In other embodiments, both the global failure counter NumFail and probe cleaning timer can be used in conjunction to make sure that the probe cleaning process is performed when (i) the global failure count threshold has been reached (affirmative determination in block 814) or when (ii) a certain amount of time has elapsed since a last probe cleaning process.

FIG. 8B illustrates a flow diagram of method for performing an automated probe cleaning process, according to an exemplary embodiment of the disclosure. In some embodiments, FIG. 8B illustrates an exemplary process 820 for implementing the probe cleaning process in block 815 of FIG. 8A. An initial step of the process 820 involves performing a coarse alignment to a probe cleaning site (block 821) wherein the X-Y-Z stage 142 is operated to move the probe cleaning site into alignment to the center of the FOV of the microscope unit. The prober unit 140 is then controlled to sweep the Z position of the X-Y-Z stage 142 through a series of discrete steps (positions), and the camera 132 of the microscope unit 130 is controlled to capture and save a digital image of the probe cleaning site in the FOV at each Z position (block 822). In some embodiments, the probe cleaning site comprises a probe cleaning pad (e.g., gel, silicon carbide, or diamond polishing film, or any other suitable probe cleaning element).

The process then determines a sharpest sample image among the plurality of sample images taken at the different Z positions (block 823). In some embodiments, the sharpest sample image is determined using, e.g., an edge detection process to identify the sample image with the sharpest edges. The X-Y-Z stage 142 is then controlled to move to the target Z position corresponding to the sharpest sample image (block 824), wherein it is assumed that at the target Z position, the sample imaging plane with the cleaning elements of the probe cleaning site is displaced from the probing plane at the known “separation distance” (e.g., 70 microns). Next, the automated probe cleaning process causes the prober unit to move in the Z direction by an amount that corresponds to the specified “separation distance” to make the initial contact between the electrical probes and the cleaning elements of the probe cleaning site (block 825). In some embodiments, the prober unit moves the stage in the Z direction by an excess of the “separation distance,” by implementing an overdrive amount (e.g., 20 microns) which allows the probe tips to be cleaned by a scrubbing action which occurs upon deflection when overdriven into the cleaning pads. The process of contacting the electrical probes and the cleaning elements of the probe cleaning site is repeated for a specified number “n” of times to ensure that the probe tips of the electrical probes have been sufficiently cleaned prior to proceeding with further probing operations. In some embodiments, an automated probe cleaning routine is performed which lands the electrical probe for “n” number of times on a cleaning pad (e.g., a gel, silicon carbide, or a diamond polishing film, etc.).

As noted above, in some embodiments, the exemplary techniques for performing electrical characterization measurements of devices using an electrical characterization system (e.g., a prober unit) that is configured to perform contact quality check operations to enable electrical probing with low contact resistance and stable contacts between electrical probes and test pads of the devices to be characterized, are implemented in conjunction with exemplary laser tuning methods which comprise iterative laser tuning methods for tuning junction resistances of superconducting tunnel junction devices (e.g., Josephson junctions). In some embodiments, iterative laser tuning methods for tuning junction resistances of Josephson junctions implement asymptotic tuning methodologies in which Josephson junctions of, e.g., qubits on a given multi-qubit device are adaptively and progressively tuned in an incremental manner to progressively shift junction resistances towards respective target junction resistances of the Josephson junctions.

In some embodiments, as explained in further detail below in conjunction with FIG. 9A, an adaptive and progressive tuning of a given Josephson junction is implemented by adaptively determining the anneal time for a given tuning iteration at a given laser power level based on a function of (i) an amount of resistance shift remaining to reach the target junction resistance and (ii) a total amount of anneal time spent for previous laser anneal iterations applied to the superconducting tunnel junction. Such iterative tuning methods are contrasted with conventional tuning methods in which Josephson junctions are tuned to a target junction resistance using a single laser shot, or single anneal iteration, which is unpredictable.

Furthermore, in some embodiments, the exemplary laser tuning methods are configured to determine a target combination of laser power level and anneal time for a given Josephson junction to perform an initial laser anneal operation (initial shot) on the given Josephson junction to achieve an initial junction resistance shift which reaches an initial target resistance (R_{initial_target}) that corresponds to, e.g., about a 50% resistance shift to a specified target junction resistance R_{target}. In particular, the initial shot is configured to achieve an initial resistance shift ΔRᵢₙᵢₜᵢₐₗ=R_{initial_target}−Rᵢₙᵢₜᵢₐₗ, where ΔRᵢₙᵢₜᵢₐₗ%=R_{target}−R_{initial_target}/ΔR_{target}×100%, where ΔR_{target}=R_{target}−Rᵢₙᵢₜᵢₐₗ. In an exemplary embodiment, the initial laser annealing operation (initial shot) for a given Josephson junction is performed at a determined combination of laser power level and anneal time to achieve a ΔRᵢₙᵢₜᵢₐₗ% of about 50%, or any other desired percentage, depending on the application.

In some embodiments, as noted above, the tuning calibration data 115 (FIG. 1) is utilized to determine a target combination of laser power level and laser anneal time to utilize for the initial shot of a given Josephson junction. The tuning calibration data 115 comprises information such as, e.g., a maximum tuning range that can be achieve for each of a plurality of different combinations of laser power and anneal time, and tuning curves that represent tuning rates for the different combinations of laser power and anneal time. In some embodiments, the calibration data is obtained by performing a calibration process which generally comprises (i) performing laser annealing operations on a set of test Josephson junctions using different combinations of laser power and anneal time, (ii) determining junction resistance shifts of the test Josephson junctions as a result of the laser annealing operations, and (iii) utilizing the determined junction resistance shifts of the test Josephson junctions to determine calibration data for configuring laser annealing operations for laser tuning Josephson junctions corresponding to the test Josephson junctions. In some embodiments, the set of test Josephson junctions reside on a test quantum chip (e.g., sister chiplet) having the test Josephson junctions which are fabricated using fabrication processes that are the same fabrication processes used to fabricate the Josephson junctions that are to be laser tuned by laser annealing operations configured using the calibration data. In other embodiments, the set of test Josephson junctions reside (e.g., in kerf regions that connect two adjacent dies) on the same quantum chip as the Josephson junctions that are to be laser tuned by laser annealing operations configured using the calibration data.

FIG. 9A illustrates a flow diagram of a method for tuning Josephson junctions, according to an exemplary embodiment of the disclosure. In some embodiments, FIG. 9A illustrates a control process for iteratively and adaptively tuning the Josephson junctions of qubits on a quantum chip, which can be performed using any of the exemplary laser annealing systems as discussed herein (e.g., laser annealing system 100 of FIG. 1). FIG. 9A illustrates an exemplary embodiment of an iterative tuning process in a round-robin format, whereby each round-robin involves iterating through all Josephson junctions, each of which is measured and “shot” one time to achieve an incremental junction resistance shift, such that each successive iteration is performed on a different Josephson junction on the quantum chip. FIG. 9A further illustrates an exemplary embodiment of a tuning process wherein before each in situ junction resistance measurement, a probe contact resistance check and probe contact stability check are performed to ensure sufficient contact between the electrical probes and the contact pads of the Josephson junction being tested.

Referring to FIG. 9A, a quantum chip is placed on the X-Y-Z stage 142 of the prober unit 140, and the control system 110 commences an automated tuning process (block 900). The automated tuning process selects an initial Josephson junction of a qubit and moves to the selected Josephson junction (block 901). In particular, the control system 110 moves the X-Y-Z stage 142 to place the initial Josephson junction into the FOV of the microscope unit 130. The tuning process initiates control operations to cause the microscope unit and the probe unit to perform a focus and alignment process to ensure a proper focus to the focal plane and proper alignment of the target Josephson junction within the FOV of the microscope unit 130 for the purpose of performing an in situ Josephson junction resistance measurement (block 902). An exemplary focusing process will be described below in conjunction with FIG. 9B. The focus ensures that the sample plane (e.g., the plane which contains the target Josephson junction) is at the focal plane (i.e., plane of focus) of the objective lens 137. The focus can be adjusted by adjusting the Z position of the X-Y-Z stage 142. As noted above, the alignment to the Josephson junction is performed using a pattern recognition process to align the Josephson junction to the center of the FOV. In some embodiments, the pattern recognition operation may be performed using a cross-correlation between the sample image and the template image to quantify the quality of the match, and the corresponding amount of offset (if any) required to optimize the match. In other embodiments, the pattern recognition operation may be performed using a machine learning process to align the target device to the center of the FOV. In addition, depending on the given iteration, the alignment can be slightly adjusted in the X and/or Y position to ensure that the electrical probes of the prober unit land on a different location of the contact pads of the Josephson junction, and not on the same location for each tuning iteration of the Josephson junction to avoid damage or excess probe marks on the contact pads and potential subsequent probing failures.

Next, the tuning process proceeds by causing the prober unit to move the contact pads of the Josephson junction in contact with the electrical probes, and perform contact resistance and contact stability checks (block 903). The contact resistance and contact stability checks that are performed in block 903 can be implemented using similar process steps as discussed above in conjunction with FIGS. 6A, 6B, 7A, 7B, 7C, 8A, and 8B.

For example, an exemplary process flow for block 903 is as follows. An initial step involves making contact between the tips of the electrical probes and the contact pads of the Josephson junction using the same or similar methods as discussed herein. Next, the process proceeds to measure the contact resistance between the electrical probes and the contact pads of the Josephson junction. The contact resistance is measured using techniques as discussed above. A determination is made as to whether the measured contact resistance is less than a contact resistance threshold. If the measured contact resistance is determined to be less than the contact resistance threshold, the tuning process proceeds to determine whether the contact is stable using, for example, the process of FIG. 7C. The contact stability check is performed to ensure that the electrical contacts between the electrical probe tips and the contact pads of the Josephson junction are stable, because intermediate or intermittent contact during an in situ junction resistance measurement operation can cause voltage spikes and potentially damage the Josephson junction being measured. In response to determining that the electrical contacts between the probes and the contact pads have low contact resistance and are stable, the tuning process proceeds to perform the in situ junction resistance measurement operation to measure the resistance of the Josephson junction (block 904). On the other hand, if either the contact resistance check or the contact stability check fails for reasons as discussed above, the tuning process can skip the junction resistance measurement for that Josephson junction, and move to a next Josephson junction and proceed with the round-robin tuning iteration for the next Josephson junction. In this instance, remedial actions can be taken (e.g., cleaning probe tips, or making contact to different areas on the contact pads of the skipped Josephson junction) to ensure that the skipped Josephson junction can be tuned in a subsequent iteration. Again, after completion of successful contact resistance and contact stability tests, an in situ junction resistance measurement is performed to determine the current junction resistance of the Josephson junction (block 904) using the same or similar resistance measurement methods as discussed herein (e.g., 4-wire, or Kelvin resistance measurement). It is to be noted that the term “current junction resistance” as used herein and in conjunction with the notation R_{current} is meant to denote a junction resistance measured in the sense of occurring in or existing at a present time, or a most recently measured junction resistance.

The tuning process determines whether the measured junction resistance R_{current} of the given Josephson junction is at or near a target junction resistance R_{target} for the given Josephson junction (block 905). For example, as noted above, a determination is made as to whether the currently measured junction resistance R_{current} is within a specified threshold percentage of the target junction resistance R_{target}, i.e., |R_{target}−R_{current}|/R_{target}≤x (e.g., x=0.003). If it is determined that the measured junction resistance R_{current} of the given Josephson junction is not at (or near) the target junction resistance R_{target} for the given Josephson junction (negative determination in block 905), the tuning process prepares for a laser anneal operation.

For example, the tuning process initiates control operations to cause the microscope unit 130 and the prober unit 140 to perform a focus and alignment process to ensure a proper focus to the focal plane and proper alignment of the target Josephson junction within the FOV of the microscope unit 130 for the purpose of performing the laser anneal operation (block 906). An exemplary focus and alignment process to prepare for a laser anneal operation will be discussed in further detail below in conjunction with FIG. 9C. In addition, the tuning process proceeds to determine the “shot” anneal time and laser power to utilize for laser annealing the given Josephson junction for the given iteration, based on the measured junction resistance (block 907).

The laser anneal operation (shot) for the given iteration is performed using the determined anneal time and laser power to laser anneal the given Josephson junction (block 908). After completion of the last anneal operation, the tuning process proceeds to the next Josephson junction to be tuned (block 901), and the process is repeated. When, at a given point in the iterative process it is determined that the currently selected Josephson junction is at its respective target resistance (affirmative determination in block 905), and that there are no remaining Josephson junctions to be further tuned (negative determination in block 909), the tuning process is terminated (block 910). In this instance, it is assumed that each Josephson junction is tuned to its respective target junction resistance and, consequently, each corresponding qubit has been tuned to its respective target transition frequency.

As noted above, FIG. 9A illustrates an adaptive tuning process which comprises an iterative laser tuning process for tuning the junction resistances of the Josephson junctions by implementing an asymptotic tuning methodology in which Josephson junctions of, e.g., qubits on a given multi-qubit device are adaptively and progressively tuned in an incremental manner to progressively shift junction resistances towards respective target junction resistances of the Josephson junctions. In some embodiments, adaptive and progressive tuning of a given Josephson junction is implemented by adaptively determining the anneal time (tₛₕₒₜ) for a given tuning iteration at a given laser power level based on a function of (i) an amount of resistance shift remaining (denoted ΔR_{remaining}) to reach the target junction resistance, and (ii) a total amount of anneal time spent for previous laser anneal iterations applied to the superconducting tunnel.

For example, an exemplary function for determining an anneal time (tₛₕₒₜ) for a given “shot” at a given laser power level is expressed as:

$${t}_{shot} ( {N}_{A} ) = \frac{Δ {R}_{t a r g e t} - Δ R}{Δ {R}_{t a r g e t}} \cdot {\sum }_{i = 1}^{{N}_{A} - 1} {t}_{shot} ( i ) for [ {N}_{A} > 1 ] ,$$

where N_{A} denotes an anneal number (or “shot” number), where ΔR_{target} denotes a difference between a target junction resistance (R_{target}) of a given Josephson junction and an initial measured resistance (denoted Rᵢₙᵢₜᵢₐₗ) of the given Josephson junction before the initial anneal operation (at N_{A}=0), and where ΔR denotes a difference between Rᵢₙᵢₜᵢₐₗ and a currently measured junction resistance (denoted R_{current}) of the given Josephson junction, which is measured in a given iteration before applying the next “shot” based on the computed anneal time tₛₕₒₜ for the given iteration. In other words, ΔR_{target}=R_{target}−Rᵢₙᵢₜᵢₐₗ, ΔR=R_{current}−Rᵢₙᵢₜᵢₐₗ, and ΔR_{remaining}=R_{target}−R_{current}. In the context of an adaptive tuning process, the parameter R_{current} denotes a current junction resistance that is measured at the beginning of each successive iteration of the adaptive tuning process, and the computation tₛₕₒₜ is performed for each successive iteration of the adaptive tuning process to determine a target anneal time for performing the laser anneal operation for given iteration. In some embodiments, the laser power level that is used in each iteration is the laser power level that was initially selected to perform the initial laser annealing operation (initial shot).

In the exemplary function for computing tₛₕₒₜ, the ratio ΔR_{target} ΔR_{target}−ΔR/ΔR_{target}=ΔR_{remaining}/ΔR_{target} provides a weight factor that represents a percentage of the amount of a remaining amount of resistance shift needed to reach the target junction resistance R_{target} of the given Josephson junction based on the total resistance shift needed to reach the target junction resistance R_{target} starting from the initial measured junction resistance Rᵢₙᵢₜᵢₐₗ of the given Josephson junction. In addition, the summation Σᵢ₌₁^{N}^{_{A}}⁻¹tₛₕₒₜ(i) provides weight factor based on the sum total time of all anneal times (total amount of all determined tₛₕₒₜ times) of all previous “shots” applied to the given Josephson junction. It is to be noted that the exemplary function for tₛₕₒₜ provides a linear combination of weight factors based on a product of ΔR_{remaining} and the total historical anneal time. In other embodiments, a function for computing tₛₕₒₜ can be based on other parameters and/or based on a non-linear function of the parameters ΔR_{remaining} and the total historical anneal time and/or other parameters, depending on, e.g., the application and/or the tuning characteristics of the Josephson junction as determined based on the associated tuning calibration data obtained using the calibration techniques as discussed herein.

Based the exemplary parameters of the function tₛₕₒₜ, at a given iteration of the tuning process, if the measured junction resistance indicates that there is a relatively large amount of resistance shift still needed to reach the target junction resistance R_{target}, the determined anneal time, tₛₕₒₜ, will be weighted (by the ratio ΔR_{remaining}/ΔR_{target}) to be longer. On the other hand, if there is a relatively small amount of resistance shift needed to reach the target junction resistance R_{target}, the anneal time, tₛₕₒₜ, will be weighted (by the ratio ΔR_{remaining}/ΔR_{target} to be shorter. As another example, if the summation Σᵢ₌₁^{N}^{_{A}}⁻¹tₛₕₒₜ (i) at a given iteration (e.g., at a given N_{A}) of the tuning process indicates a relatively large total amount of annealing has been performed on the given Josephson junction, this provides an indication that the given Josephson junction is tuning slowly, so that the next anneal time, tₛₕₒₜ, will be weighted (by the sum total anneal time) to be relatively long. On the other hand, if the summation Σᵢ₌₁^{N}^{_{A}}⁻¹tₛₕₒₜ (i) at a given iteration of the tuning process indicates a relatively small total duration of annealing has been performed on the given Josephson junction, this provides an indication that the given Josephson junction is tuning relatively fast, so that the next anneal time, tₛₕₒₜ, will be weighted (by the sum total anneal time) to be relatively short.

The exemplary laser tuning methods as discussed herein are contrasted with conventional tuning methods in which Josephson junctions are tuned to a target junction resistance using a single laser shot, which is unpredictable. The exemplary junction tuning techniques as disclosed herein are configured to perform an initial “shot” on a given Josephson junction to shift the junction resistance from the initial resistance (Rᵢₙᵢₜᵢₐₗ) to a junction resistance that is, e.g., about 50% to the target junction resistance (R_{target}), followed by iteratively tuning the junction resistance of the given Josephson junction using multiple shots with anneal times that are adaptively determined for each shot to ensure a gradual approach to a target junction resistance, while accounting for relaxation of the junction resistances after laser annealing, which may require a period of time delay to settle closer to their final values. In an exemplary embodiment of a laser tuning progression after the first shot, the junctions (starting from the first, and progressing to the last) are each shot once in succession, and the process repeats starting at the first junction again. In this manner, the first junction resistance has time to relax and stabilize close to its final value prior to the subsequent shots. In another embodiment of a laser tuning progression after the first shot, each junction may be iteratively annealed to completion prior to annealing the next junction. In this case, a time delay may be implemented in between successive anneal iterations on the same junction, to allow the junction resistances to relax and stabilize near their final values to improve the accuracy of approaching resistance targets.

FIG. 9B illustrates a flow diagram of a method for focusing and aligning to a target Josephson junction for the purpose of performing an in situ Josephson junction resistance measurement, according to an exemplary embodiment of the disclosure. In some embodiments, FIG. 9A illustrates an exemplary process 920 for implementing the focus/alignment processes in block 902 of FIG. 9A. An initial step of the process 920 involves performing a coarse alignment in which the X-Y-Z stage 142 is controllably operated to move the target Josephson junction in alignment to a center of the FOV of the microscope unit (block 921). The prober unit 140 is then controlled to sweep the Z position of the X-Y-Z stage 142 through a series of discrete steps (positions), and the camera 132 of the microscope unit 130 is controlled to capture and save a digital image of the sample (sample image) in the FOV at each Z position (block 922).

The tuning process then determines a sharpest sample image among the plurality of sample images taken at the different Z positions (block 923). In some embodiments, the sharpest sample image is determined using, e.g., an edge detection process to identify the sample image with the sharpest edges (e.g., sharpest edges of contact pads to which the electrical probes will make contact). The X-Y-Z stage 142 is then controlled to move to the target Z position corresponding to the sharpest sample image (block 924), wherein it is assumed that at the target Z position, the sample imaging plane with the contact pads is displaced from the probing plane at a known distance (e.g., 70 microns). Finally, an optional step of slightly adjusting the X and/or Y position of the quantum chip can be performed to provide some small offset from the original center alignment (block 925), which allows the probe tips of the electrical probes to make contact to the contact pads of the given Josephson junction in desired target contact positions which are different from the contact positions made to the contact pads for previous in situ junction resistance measurements of previous iterations.

FIG. 9C illustrates a flow diagram of a method for focusing and aligning to a target Josephson junction for the purpose of performing a laser anneal process, according to an exemplary embodiment of the disclosure. In some embodiments, FIG. 9C illustrates an exemplary process 930 for implementing the focus/alignment processes in block 906 of FIG. 9A. An initial step of the process 930 involves performing a coarse alignment process (block 931) in which the X-Y-Z stage 142 is controllably operated to, e.g., move back to the Z position that was previously determined to place the image plane at or near the focal plane as a result of the focusing step (e.g., block 924, FIG. 9B) performed for the in situ junction resistance measurement. In this instance, it is assumed that the target Josephson junction is placed back to a position that is aligned (or nearly aligned) to the center of the FOV of the microscope unit. A pattern recognition operation is performed to determine an amount of offset (if any) between the sample image taken of the Josephson junction in the FOV and a template image of the Josephson junction aligned to the center of the FOV (block 932). In some embodiments, the pattern recognition operation may be performed using a cross-correlation between the sample image and the template image to quantify the quality of the match, and the corresponding amount of offset (if any) required to optimize the match. In other embodiments, the pattern recognition operation may be performed using a machine learning process to align the target device to the center of the FOV.

Next, a determination is then made as to whether the offset as determined exceeds an offset threshold (block 933). For example, such a determination can be made to determine whether the sample image of the Josephson junction in the FOV is misaligned in the X direction, the Y direction, or in both the X and Y directions, by some offset amount which exceeds an offset threshold. If the X offset and/or Y offset is determined to exceed the offset threshold (affirmative determination in block 933), the X-Y-Z stage 142 is controllably moved in the X and/or Y direction by the determined offset amount to correct for the misalignment in the X direction and/or Y direction (block 934), and the pattern recognition and offset determination steps (blocks 932 and 933) are repeated. Once the sample image of the Josephson junction in the FOV is determined to be aligned to the template image, the tuning process proceeds to the laser anneal operation (block 935). In some embodiments, a maximum number of repeats of blocks 932, 933, 934 may be performed (e.g., 5 times), to ensure that the alignment process 930 has a bounded time of operation.

FIG. 9D schematically illustrates a process for aligning a laser spot pattern to a Josephson junction of a quantum bit, according to an exemplary embodiment of the disclosure. In particular, similar to that shown in FIGS. 5A and 5B, FIG. 9D schematically illustrates an exemplary FOV 510 which schematically illustrates a superconducting transmon qubit 530. FIG. 9D schematically illustrates an exemplary alignment process 940 in which an exemplary pattern of laser spots 941 and 942 can be used to laser anneal the Josephson junction 533. In particular, the exemplary pattern of laser spots 941 and 942 comprises 4 spots which correspond to, e.g., four laser beams generated by the laser beam shaper 135 (FIG. 1) implemented using a 2-by-2 diffractive beam splitter generate 4 laser beams that are projected onto the surface of the quantum chip 160 via the microscope unit 130. As schematically illustrated in FIG. 9D, the Josephson junction 533 is aligned in the FOV 510 such that the laser beam spot pattern comprises two laser spots 941 positioned on one side (e.g., above) of the Josephson junction 533, and two laser spots 942 positioned on an opposite side (e.g., below) the Josephson junction 533, wherein the laser spots 941 and 942 are positioned to illuminate (and heat) regions of the upper surface of the quantum chip 160 in proximity to the Josephson junction 533, but not directly illuminate the Josephson junction 533. In other embodiments, other types of laser spot patterns can be utilized to laser anneal the Josephson junction 533. For example, the different laser spot patterns include, e.g., a 1-spot pattern, a 2-spot pattern, a 6-spot pattern, etc., depending on the application and/or the geometry of the features that are being laser annealed.

It is to be noted that while FIG. 9D illustrates a superconducting qubit 530 comprising a single Josephson junction 533, other types of superconducting qubits or quantum devices can have multiple Josephson junctions, which can be laser annealed concurrently using a suitable laser spot pattern. For example, some quantum devices, such as tunable qubit couplers, comprise a SQUID, wherein the SQUID comprises a pair of Josephson junctions which are connected in parallel to form a superconducting loop (referred to as SQUID loop) through which an external magnetic flux ϕ can be threaded to control operation of the tunable qubit coupler. In this regard, the Josephson junctions of a SQUID can be laser annealed and tuned concurrently by using a suitable laser spot pattern that is configured to heat the substrate regions surrounding the two Josephson junctions of the SQUID. It is to be further noted that while fixed-frequency qubits such as shown in FIG. 9D are candidates for laser tuning using the exemplary laser tuning techniques as disclosed herein, it is to be understood that such exemplary techniques may be implemented to laser tune any quantum element comprising at least one Josephson junction, including, but not limited to fixed-frequency transmon qubits, SQUID devices, and the like.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1000 of FIG. 10 contains an example of an environment for the execution of at least some of the computer code (block 1026) comprising data processing and control algorithms for performing various operations such as electrical characterization measurements (e.g., junction resistance measurements), contact resistance and contact stability check operations, laser annealing and tuning operations, imaging, pattern recognition, computer vision inspection, calibration operations, etc., and other computer automated control and data processing operations as discussed herein for performing the various methods as shown and described, for example, in conjunction with FIGS. 1, 2, 3, 4, 5A, 5B, 6A, 6B, 7A, 7B, 7C, 8A, 8B, 9A, 9B, 9C, and 9D. In addition to block 1026, computing environment 1000 includes, for example, computer 1001, wide area network (WAN) 1002, end user device (EUD) 1003, remote server 1004, public cloud 1005, and private cloud 1006. In this embodiment, computer 1001 includes processor set 1010 (including processing circuitry 1020 and cache 1021), communication fabric 1011, volatile memory 1012, persistent storage 1013 (including operating system 1022 and block 1026, as identified above), peripheral device set 1014 (including user interface (UI), device set 1023, storage 1024, and Internet of Things (IoT) sensor set 1025), and network module 1015. Remote server 1004 includes remote database 1030. Public cloud 1005 includes gateway 1040, cloud orchestration module 1041, host physical machine set 1042, virtual machine set 1043, and container set 1044.

Computer 1001 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1030. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1001, to keep the presentation as simple as possible. Computer 1001 may be located in a cloud, even though it is not shown in a cloud in FIG. 10. On the other hand, computer 1001 is not required to be in a cloud except to any extent as may be affirmatively indicated.

Processor set 1010 includes one, or more, computer processors of any type now known or to be developed in the future. Processing circuitry 1020 may be distributed over multiple packages, for example, multiple, coordinated integrated circuit chips. Processing circuitry 1020 may implement multiple processor threads and/or multiple processor cores. Cache 1021 is memory that is located in the processor chip package(s) and is typically used for data or code that should be available for rapid access by the threads or cores running on processor set 1010. Cache memories are typically organized into multiple levels depending upon relative proximity to the processing circuitry. Alternatively, some, or all, of the cache for the processor set may be located “off chip.” In some computing environments, processor set 1010 may be designed for working with qubits and performing quantum computing.

Computer readable program instructions are typically loaded onto computer 1001 to cause a series of operational steps to be performed by processor set 1010 of computer 1001 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1021 and the other storage media discussed below. The program instructions, and associated data, are accessed by processor set 1010 to control and direct performance of the inventive methods. In computing environment 1000, at least some of the instructions for performing the inventive methods may be stored in block 1026 in persistent storage 1013.

Communication fabric 1011 comprises the signal conduction paths that allow the various components of computer 1001 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1012 is any type of volatile memory now known or to be developed in the future. Examples include dynamic type random access memory (RAM) or static type RAM. Typically, the volatile memory is characterized by random access, but this is not required unless affirmatively indicated. In computer 1001, the volatile memory 1012 is located in a single package and is internal to computer 1001, but, alternatively or additionally, the volatile memory may be distributed over multiple packages and/or located externally with respect to computer 1001.

Persistent storage 1013 is any form of non-volatile storage for computers that is now known or to be developed in the future. The non-volatility of this storage means that the stored data is maintained regardless of whether power is being supplied to computer 1001 and/or directly to persistent storage 1013. Persistent storage 1013 may be a read only memory (ROM), but typically at least a portion of the persistent storage allows writing of data, deletion of data and re-writing of data. Some familiar forms of persistent storage include magnetic disks and solid-state storage devices. Operating system 1022 may take several forms, such as various known proprietary operating systems or open source Portable Operating System Interface type operating systems that employ a kernel. The code included in block 1026 typically includes at least some of the computer code involved in performing the inventive methods.

Peripheral device set 1014 includes the set of peripheral devices of computer 1001. Data communication connections between the peripheral devices and the other components of computer 1001 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1023 may include components such as a display screen, speaker, microphone, wearable devices (such as goggles and smart watches), keyboard, mouse, printer, touchpad, game controllers, and haptic devices. Storage 1024 is external storage, such as an external hard drive, or insertable storage, such as an SD card. Storage 1024 may be persistent and/or volatile. In some embodiments, storage 1024 may take the form of a quantum computing storage device for storing data in the form of qubits. In embodiments where computer 1001 is required to have a large amount of storage (for example, where computer 1001 locally stores and manages a large database) then this storage may be provided by peripheral storage devices designed for storing very large amounts of data, such as a storage area network (SAN) that is shared by multiple, geographically distributed computers. IoT sensor set 1025 is made up of sensors that can be used in Internet of Things applications. For example, one sensor may be a thermometer and another sensor may be a motion detector.

Network module 1015 is the collection of computer software, hardware, and firmware that allows computer 1001 to communicate with other computers through WAN 1002. Network module 1015 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1015 are performed on the same physical hardware device. In other embodiments (for example, embodiments that utilize software-defined networking (SDN)), the control functions and the forwarding functions of network module 1015 are performed on physically separate devices, such that the control functions manage several different network hardware devices. Computer readable program instructions for performing the exemplary inventive methods can typically be downloaded to computer 1001 from an external computer or external storage device through a network adapter card or network interface included in network module 1015.

WAN 1002 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1003 is any computer system that is used and controlled by an end user (for example, a customer of an enterprise that operates computer 1001), and may take any of the forms discussed above in connection with computer 1001. EUD 1003 typically receives helpful and useful data from the operations of computer 1001. For example, in a hypothetical case where computer 1001 is designed to provide a recommendation to an end user, this recommendation would typically be communicated from network module 1015 of computer 1001 through WAN 1002 to EUD 1003. In this way, EUD 1003 can display, or otherwise present, the recommendation to an end user. In some embodiments, EUD 1003 may be a client device, such as thin client, heavy client, mainframe computer, desktop computer and so on.

Remote server 1004 is any computer system that serves at least some data and/or functionality to computer 1001. Remote server 1004 may be controlled and used by the same entity that operates computer 1001. Remote server 1004 represents the machine(s) that collect and store helpful and useful data for use by other computers, such as computer 1001. For example, in a hypothetical case where computer 1001 is designed and programmed to provide a recommendation based on historical data, then this historical data may be provided to computer 1001 from remote database 1030 of remote server 1004.

Public cloud 1005 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1005 is performed by the computer hardware and/or software of cloud orchestration module 1041. The computing resources provided by public cloud 1005 are typically implemented by virtual computing environments that run on various computers making up the computers of host physical machine set 1042, which is the universe of physical computers in and/or available to public cloud 1005. The virtual computing environments (VCEs) typically take the form of virtual machines from virtual machine set 1043 and/or containers from container set 1044. It is understood that these VCEs may be stored as images and may be transferred among and between the various physical machine hosts, either as images or after instantiation of the VCE. Cloud orchestration module 1041 manages the transfer and storage of images, deploys new instantiations of VCEs and manages active instantiations of VCE deployments. Gateway 1040 is the collection of computer software, hardware, and firmware that allows public cloud 1005 to communicate through WAN 1002.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1006 is similar to public cloud 1005, except that the computing resources are only available for use by a single enterprise. While private cloud 1006 is depicted as being in communication with WAN 1002, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1005 and private cloud 1006 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system, comprising:
a prober unit comprising electrical probes; and
a control unit configured to:
cause the prober unit to make contact between the electrical probes and contact pads of a target device;
cause the prober unit to increment a contact overdrive by a specified amount to increase a contact pressure between the electrical probes and the contact pads of the target device;
measure a contact resistance between the electrical probes and the contact pads of the target device, subsequent to incrementing the contact overdrive;
compare the measured contact resistance with a contact resistance threshold; and
determine whether to perform an electrical characterization measurement of the target device, based on a result of comparing the measured contact resistance with the contact resistance threshold.

2. The system of claim 1, wherein the control unit is configured to perform the electrical characterization measurement of the target device, in response to determining that the measured contact resistance is less than the contact resistance threshold.

3. The system of claim 1, wherein in response to determining that the measured contact resistance is not less than the contact resistance threshold, the control unit is configured to:
cause the prober unit to incrementally increase the amount of contact overdrive by one or more contact overdrive increments of a specified fixed amount;
remeasure the contact resistance between the electrical probes and the contact pads of the target device, subsequent to each contact overdrive increment of the specified fixed amount; and
perform the electrical characterization measurement when the remeasured contact resistance between the electrical probes and the contact pads of the target device is determined to be less than the contact resistance threshold.

4. The system of claim 3, wherein the control unit is configured to:
cause the prober unit to incrementally increase the amount of contact overdrive to no more than a specified maximum amount of contact overdrive; and
skip the electrical characterization measurement of the target device, in response to determining that the contact resistance between the electrical probes and the contact pads of the target device is still not less than the contact resistance threshold after a total amount of contact overdrive has reached the specified maximum amount of contact overdrive.

5. The system of claim 1, wherein in determining whether to perform the electrical characterization measurement of the target device, based on the result of comparing the measured contact resistance with the contact resistance threshold, the control unit is configured to:
perform a contact stability check process to determine whether the contact between the electrical probes and contact pads of the target device is stable, in response to determining that the measured contact resistance is less than the contact resistance threshold; and
perform the electrical characterization measurement, in response to determining that the contact between the electrical probes and contact pads of the target device is stable.

6. The system of claim 5, wherein in performing the contact stability check process, the control unit is configured to:
repeat a contact resistance measurement operation for a specified number of times, to obtain a plurality of contact resistance measurements;
determine an amount of variation of the plurality of contact resistance measurements; and
determine whether the contact between the electrical probes and the contact pads of the target device is stable, based on the determined amount of variation.

7. The system of claim 5, wherein the control unit is configured to:
cause the prober unit to increase the amount of contact overdrive by a specified fixed amount, in response to determining that the contact between the electrical probes and contact pads of the target device is not stable; and
repeat the contact stability check process with the contact between the electrical probes and contact pads of the target device at the increased amount of contact overdrive.

8. The system of claim 7, wherein the control unit is configured to skip the electrical characterization measurement of the target device, in response to the control unit determining that the contact between the electrical probes and the contact pads of the target device is still not stable after a total amount of contact overdrive has reached a specified maximum amount of contact overdrive.

9. The system of claim 1, wherein:
the prober unit further comprises an X-Y-Z stage on which the target device is mounted;
the control unit is configured to adjust a Z position of the X-Y-Z stage to bring the contact pads of the target device into contact with the electrical probes; and
the control unit is configured to increment the Z position of the X-Y-Z stage to increment the contact overdrive by the specified amount.

10. The system of claim 1, wherein:
the electrical probes comprise a 4-wire probe; and
the electrical characterization measurement comprises a 4-wire resistance measurement operation to measure a resistance of the target device.

11. A system, comprising:
an optical unit;
a prober unit comprising electrical probes; and
a control unit configured to control the prober unit and the optical unit;
wherein the optical unit and the prober unit comprise an integrated configuration to perform laser annealing operations for tuning junction resistances of superconducting tunnel junction devices on a quantum chip, and to perform in situ resistance measurements to measure the junction resistances of the superconducting tunnel junction devices on the quantum chip;
wherein in performing an in situ resistance measurement to measure a junction resistance of a target superconducting tunnel junction device, the control unit is configured to:
cause the prober unit to make contact between the electrical probes and contact pads of the target superconducting tunnel junction device;
cause the prober unit to increment a contact overdrive by a specified amount to increase a contact pressure between the electrical probes and the contact pads of the target superconducting tunnel junction device;
measure a contact resistance between the electrical probes and the contact pads of the target superconducting tunnel junction device, subsequent to incrementing the contact overdrive;
compare the measured contact resistance with a contact resistance threshold; and
determine whether to perform the in situ resistance measurement to measure the junction resistance of the target superconducting tunnel junction device, based on a result of comparing the measured contact resistance with the contact resistance threshold.

12. The system of claim 11, wherein the control unit is configured to perform the in situ resistance measurement to measure the junction resistance of the target superconducting tunnel junction device, in response to determining that the measured contact resistance is less than the contact resistance threshold.

13. The system of claim 11, wherein in response to determining that the measured contact resistance is not less than the contact resistance threshold, the control unit is configured to:
cause the prober unit to incrementally increase the amount of contact overdrive by one or more contact overdrive increments of a specified fixed amount;
remeasure the contact resistance between the electrical probes and the contact pads of the target superconducting tunnel junction device, subsequent to each contact overdrive increment of the specified fixed amount; and
perform the in situ resistance measurement to measure the junction resistance of the target superconducting tunnel junction device when the remeasured contact resistance between the electrical probes and the contact pads of the target superconducting tunnel junction device is determined to be less than the contact resistance threshold.

14. The system of claim 13, wherein the control unit is configured to:
cause the prober unit to incrementally increase the amount of contact overdrive to no more than a specified maximum amount of contact overdrive; and
skip the in situ resistance measurement of the target superconducting tunnel junction device, in response to determining that the contact resistance between the electrical probes and the contact pads of the target superconducting tunnel junction device is still not less than the contact resistance threshold after a total amount of contact overdrive has reached the specified maximum amount of contact overdrive.

15. The system of claim 11, wherein:
in determining whether to perform the in situ resistance measurement to measure the junction resistance of the target superconducting tunnel junction device, based on the result of comparing the measured contact resistance with the contact resistance threshold, the control unit is configured to:
perform a contact stability check process to determine whether the contact between the electrical probes and contact pads of the target superconducting tunnel junction device is stable, in response to determining that the measured contact resistance is less than the contact resistance threshold; and
perform the in situ resistance measurement, in response to determining that the contact between the electrical probes and contact pads of the target superconducting tunnel junction device is stable; and
in performing the contact stability check process, the control unit is configured to:
repeat a contact resistance measurement operation for a specified number of times, to obtain a plurality of contact resistance measurements;
determine an amount of variation of the plurality of contact resistance measurements; and
determine whether the contact between the electrical probes and the contact pads of the target superconducting tunnel junction device is stable, based on the determined amount of variation.

16. The system of claim 15, wherein the control unit is configured to:
cause the prober unit to increase the amount of contact overdrive by a specified fixed amount, in response to determining that the contact between the electrical probes and the contact pads of the target superconducting tunnel junction device is not stable;
repeat the contact stability check process with the contact between the electrical probes and contact pads of the target superconducting tunnel junction device at the increased amount of contact overdrive; and
skip the in situ resistance measurement to measure the junction resistance of the target superconducting tunnel junction device, in response to the control unit determining that the contact between the electrical probes and the contact pads of the target superconducting tunnel junction device is still not stable after a total amount of contact overdrive has reached a specified maximum amount of contact overdrive.

17. The system of claim 11, wherein the control unit is configured to cause the prober unit to perform a probe cleaning process to clean the electrical probes in response to at least one of: an expiration of a specified time interval subsequent to a previous probe cleaning process; and upon an occurrence of a specified number of successive failed attempts to make an acceptable contact between the electrical probes and contact pads of respective superconducting tunnel junction devices for the specified number of attempted in situ resistance measurements of the respective superconducting tunnel junction devices.

18. A method, comprising:
making contact between electrical probes of a prober unit and contact pads of a target device;
incrementing a contact overdrive by a specified amount to increase a contact pressure between the electrical probes and the contact pads of the target device;
measuring a contact resistance between the electrical probes and the contact pads of the target device, subsequent to incrementing the contact overdrive;
comparing the measured contact resistance with a contact resistance threshold; and
determining whether to perform an electrical characterization measurement of the target device, based on a result of comparing the measured contact resistance with the contact resistance threshold.

19. The method of claim 18, further comprising:
in response to determining that the measured contact resistance is less than the contact resistance threshold, performing the electrical characterization measurement of the target device; and
in response to determining that the measured contact resistance is not less than the contact resistance threshold:
incrementally increasing the amount of contact overdrive by one or more contact overdrive increments of a specified fixed amount;
remeasuring the contact resistance between the electrical probes and the contact pads of the target device, subsequent to each contact overdrive increment of the specified fixed amount; and
one of: (i) performing the electrical characterization measurement of the target device, when the remeasured contact resistance between the electrical probes and the contact pads of the target device is determined to be less than the contact resistance threshold, and (ii) skipping the electrical characterization measurement of the target device, in response to determining that the contact resistance between the electrical probes and the contact pads of the target device is still not less than the contact resistance threshold after a total amount of contact overdrive has reached a specified maximum amount of contact overdrive.

20. The method of claim 18, wherein determining whether to perform the electrical characterization measurement of the target device, based on the result of comparing the measured contact resistance with the contact resistance threshold, comprises:
performing a contact stability check process to determine whether the contact between the electrical probes and contact pads of the target device is stable, in response to determining that the measured contact resistance is less than the contact resistance threshold; and
performing the electrical characterization measurement, in response to determining that the contact between the electrical probes and contact pads of the target device is stable;
wherein performing the contact stability check process, comprises:
repeating a contact resistance measurement operation for a specified number of times, to obtain a plurality of contact resistance measurements;
determining an amount of variation of the plurality of contact resistance measurements; and
determining whether the contact between the electrical probes and the contact pads of the target device is stable, based on the determined amount of variation.
